(19) United States
(12) Patent Application Publication
(10) Pub. No.: US 2026/0033064 A1
(43) Pub. Date: Jan. 29, 2026

(54) DISPLAY APPARATUS

(71) Applicant: LG Display Co., Ltd., Seoul (KR)

(72) Inventors: DongGeun BAE, Paju-si (KR); Sohee KIM, Paju-si (KR)

(73) Assignee: LG Display Co., Ltd., Seoul (KR)

(21) Appl. No.: 19/248,061

(22) Filed: Jun. 24, 2025

(30) Foreign Application Priority Data
Jul. 23, 2024 (KR) 10-2024-0097222

(51) Int. Cl. H10H 29/39

(52) U.S. Cl. CPC H10H 29/39

(57) ABSTRACT

A display apparatus is provided in the present disclosure. The display apparatus includes a substrate, a pixel driving circuit disposed on the substrate, a bank disposed on the pixel driving circuit, a first electrode which is disposed on the bank and is connected to the pixel driving circuit, a plurality of solder patterns disposed on the plurality of first electrodes, a micro LED disposed on one solder pattern, among the plurality of solder patterns, a first optical layer which is disposed so as to enclose the micro LED and exposes another solder pattern, among the plurality of solder patterns, and a second electrode which is disposed on the micro LED and the first optical layer and exposes the another solder pattern. Accordingly, a short-circuit defect between the solder pattern and the second electrode may be minimized or reduced.

### CROSS-REFERENCE TO RELATED APPLICATIONS

This application claims the priority of Korean Patent Application No. 10-2024-0097222 filed on Jul. 23, 2024, in the Korean Intellectual Property Office, the entire disclosure of which is expressly incorporated into the present application by reference as if fully set forth herein.

### TECHNICAL FIELD

The present disclosure relates to an apparatus, and particularly to, for example, without limitation, a display apparatus.

### DESCRIPTION OF THE RELATED ART

Display apparatuses may be applied to various electronic devices, such as TVs, mobile phones, notebooks, and tablets.

As display apparatuses, there are an organic light emitting display (OLED) which is a self-emitting device and a liquid crystal display (LCD) which requires a separate light source.

Recently, a display apparatus including a light emitting diode (LED) is attracting attention as a next generation display apparatus. The light emitting diode is formed of an inorganic material, rather than an organic material so that lighting speed is faster, and luminous efficiency is excellent, and an image with a higher luminance is displayed, as compared with the liquid crystal display or the organic light emitting display.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

The disclosed display apparatus includes several structural and process enhancements that improve reliability and manufacturing efficiency in micro LED displays. To address the risk of electrical short circuits caused by missing micro LEDs, the design incorporates a first optical layer that encloses the micro LED while exposing unpopulated solder pads. A second electrode is applied over the optical layer and selectively removed from sub-pixels where a micro LED was not successfully transferred, as determined by a lighting test. Each sub-pixel includes both a primary and a redundant micro LED, allowing selection of a functioning element during inspection to improve yield.

The apparatus also features a flexible layer configuration using ductile materials and stress-relief electrode patterns. Insulating and buffer layers are partially removed in defined bendable regions to reduce mechanical stress and prevent cracking. A shared second electrode structure simplifies the circuit layout, and each pixel driving circuit is configured to operate multiple micro LEDs, reducing area usage and circuit complexity. These features contribute to improved display durability, reduced power consumption, and enhanced process control during fabrication.

Various embodiments of the present disclosure provide a display apparatus in which a short-circuit defect is minimized or reduced.

Various embodiments of the present disclosure provide a display apparatus which suppresses a short-circuit between electrodes due to the non-transferring of a micro LED to be driven with a low power in terms of reduction of a power consumption.

Technical benefits of the present disclosure are not limited to the above-mentioned benefits, and other benefits, which are not mentioned above, can be clearly understood by those skilled in the art from the following descriptions.

According to an aspect of the present disclosure, a display apparatus includes a substrate, a pixel driving circuit disposed on the substrate, a bank disposed on the pixel driving circuit, a first electrode which is disposed on the bank and is connected to the pixel driving circuit, a plurality of solder patterns disposed on the plurality of first electrodes, a micro LED disposed on one solder pattern, among the plurality of solder patterns, a first optical layer which is disposed so as to enclose the micro LED and exposes another solder pattern, among the plurality of solder patterns, and a second electrode which is disposed on the micro LED and the first optical layer and exposes the another solder pattern. Accordingly, a short-circuit defect between the solder pattern and the second electrode may be minimized or reduced.

Other detailed matters of the exemplary embodiments are included in the detailed description and the drawings.

According to the present disclosure, a sub pixel in which the micro LED is not transferred is detected by a lighting test to remove a second electrode of the corresponding sub pixels, thereby avoiding the short-circuit defect in advance.

According to the present disclosure, a second electrode which is in contact with the solder pattern due to the non-transferring defect of the micro LED is removed to suppress the short-circuit defect between the solder pattern and the second electrode.

According to the present disclosure, a potential defect due to the short-circuit between the electrodes due to the non-transferring of the micro LED is minimized or reduced and the lifespan of the display apparatus is improved to be driven at a low power in terms of reduction of a power consumption.

The effects according to the present disclosure are not limited to the contents exemplified above, and more various effects are included in the present specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an exemplary embodiment of the present disclosure;

FIG. 2 is a plan view of a display apparatus according to an exemplary embodiment of the present disclosure;

FIG. 3 is an enlarged view of a display apparatus according to an exemplary embodiment of the present disclosure;

FIG. 4 is a view illustrating a circuit structure according to an exemplary embodiment of the present disclosure;

FIG. 5 is a plan view of a display apparatus according to an exemplary embodiment of the present disclosure;

FIG. 6 is a plan view of a display apparatus according to an exemplary embodiment of the present disclosure;

FIG. 7 is a plan view of a display apparatus according to an exemplary embodiment of the present disclosure;

FIG. 8 is a cross-sectional view taken along VIII-VIII′ of FIG. 3;

FIG. 9 is a cross-sectional view of a display apparatus according to an exemplary embodiment of the present disclosure;

FIG. 10 is a plan view of a display apparatus according to an exemplary embodiment of the present disclosure;

FIGS. 11A and 11B are plan views of a display apparatus according to an exemplary embodiment of the present disclosure;

FIG. 12 is a plan view of a display apparatus according to another exemplary embodiment of the present disclosure;

FIGS. 13A and 13B are plan views of a display apparatus according to another exemplary embodiment of the present disclosure;

FIG. 14 is a cross-sectional view of a display apparatus according to another exemplary embodiment of the present disclosure;

FIGS. 15A to 15F are process diagrams of a manufacturing method of a display apparatus according to another exemplary embodiment of the present disclosure; and

FIGS. 16 to 19 are views illustrating devices to which a display apparatus according to exemplary embodiments of the present disclosure is applied.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily obscure a gist of the inventive concept, the detailed description thereof will be omitted or may be briefly provided. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Like reference numerals generally denote like elements throughout the specification. Further, in the following description of the present disclosure, a detailed explanation of known related technologies may be omitted or may be briefly provided to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Any implementation described herein as an “example” is not necessarily to be construed as preferred or advantageous over other implementations.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When explaining temporal relationships, terms such as “after,” “following,” “subsequent to,” or “before,” etc., may include non-consecutive cases unless terms like “immediately” or “directly” are used.

Terms such as “first,” “second,” etc., are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction,” “second direction,” “third direction,” “X-axis direction,” “Y-axis direction,” and “Z-axis direction” should not be interpreted solely as geometric relationships perpendicular to each other, but may indicate broader directionality within the range where the configuration of the present disclosure can function.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The features of various embodiments in the present disclosure may be partially or wholly combined or associated with each other, various technical interlocking and operations are possible, and each embodiment may be implemented independently of each other or may be implemented together in an associated relationship.

It will be apparent to those skilled in the art that various modifications and variations can be made to the embodiments of the present disclosure without departing from the technical idea or scope of the present disclosure. Thus, it is intended that the present disclosure covers the modifications and variations of this disclosure provided they come within the scope of the appended claims and their equivalents.

Hereinafter, a display apparatus according to exemplary embodiments of the present disclosure will be described in detail with reference to accompanying drawings.

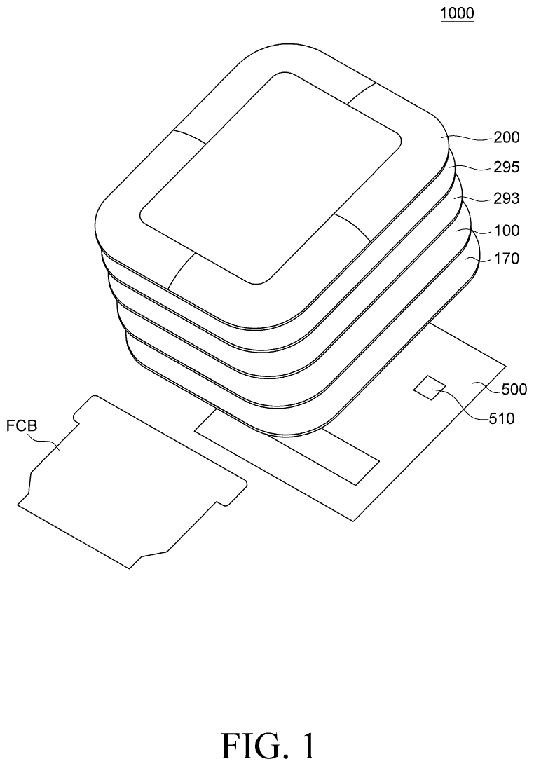

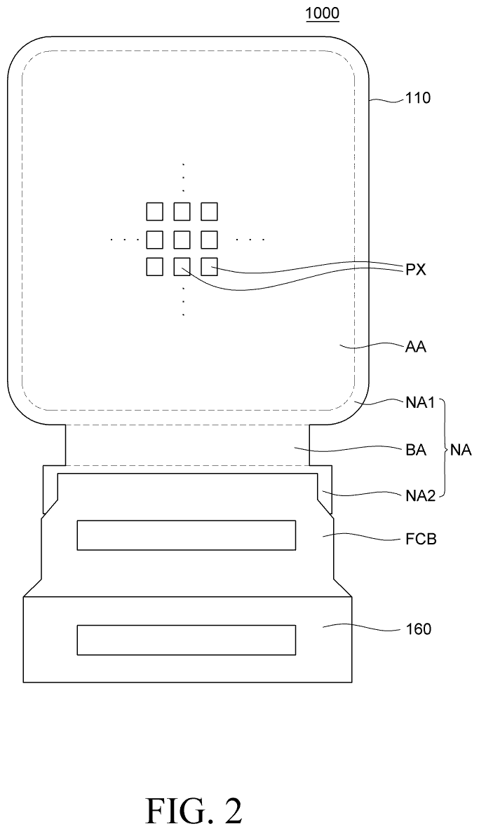

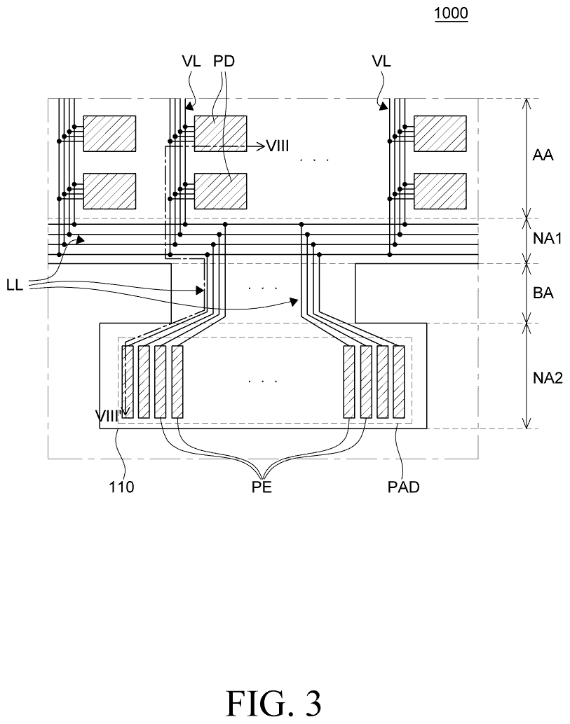

FIG. 1 is a perspective view illustrating a display apparatus according to an exemplary embodiment of the present disclosure. FIG. 2 is a plan view of a display apparatus according to an exemplary embodiment of the present disclosure. FIG. 3 is an enlarged view of a display apparatus according to an exemplary embodiment of the present disclosure.

Referring to FIGS. 1 to 3, a display apparatus 1000 according to an exemplary embodiment of the present disclosure includes a display panel 100, a polarization layer 293, an adhesive layer 295, a cover member 120, a support substrate 170, a flexible circuit board FCB, and a printed circuit board 160.

For example, the display panel 100 of the display apparatus 1000 includes a substrate 110. The substrate 110 may be a member which supports other components of the display apparatus 1000. The substrate 110 is formed of an insulating material. For example, the substrate 110 may be formed of glass or resin. Further, the substrate 110 may also be formed of a material having flexibility. For example, the substrate 110 may be formed of a plastic material having flexibility, such as polyimide (PI), but the exemplary embodiments of the present disclosure are not limited thereto.

The display panel 100 may implement information, videos, and/or images which are provided to users. For example, the display panel 100 includes an active area AA and a non-active area NA. For example, the substrate 110 includes an active area AA and a non-active area NA. However, the active area AA and the non-active area NA are not mentioned to be limited to the substrate 110, but may be mentioned for the entire display apparatus 1000.

The active area AA is an area where images are displayed. The active area AA includes a plurality of pixels PX. Each of the plurality of pixels PX may be configured by a plurality of sub pixels. A plurality of micro LEDs is disposed in each of the plurality of sub pixels. The plurality of micro LEDs may be configured in different manners depending on the type of the display apparatus 1000. For example, if the display apparatus 1000 is an inorganic light emitting display apparatus, the micro LEDs may be a micro light emitting diode, but the exemplary embodiments of the present disclosure are not limited thereto.

The non-active area NA is an area where no image is displayed. In the non-active area NA, various wiring lines and circuits for driving the plurality of pixels PX of the active area AA are disposed. For example, in the non-active area NA, various wiring lines and driving circuits are mounted and a pad unit PAD to which an integrated circuit and a printed circuit are connected is disposed, but the exemplary embodiments of the present disclosure are not limited thereto.

For example, the driving circuit may be a data driving circuit and/or a gate driving circuit, but the exemplary embodiments of the present disclosure are not limited thereto. Wiring lines through which a control signal for controlling driving circuits is supplied are disposed. For example, the control signal includes various timing signals including a clock signal, an input data enable signal, and synchronization signals, but the exemplary embodiments of the present disclosure are not limited thereto. The control signal is received through the pad unit PAD. For example, in the non-active area NA, link lines LL is disposed to transmit signals. For example, driving components, such as the flexible circuit board FCB and the printed circuit board 160, are connected to the pad unit PAD.

According to the present specification, the non-active area NA includes a first non-active area NA1, a bending area BA, and a second non-active area NA2. For example, the first non-active area NA1 is an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD is disposed therein. For example, the bending area BA is in a bent state and the other areas of the substrate 110 excluding the bending area BA may be in a flat state. In this case, as the bending area BA is bent, the second non-active area NA2 is located on a rear surface of the active area AA, but the exemplary embodiments of the present disclosure are not limited thereto.

The active area AA of the substrate 110 or the display apparatus 1000 may be configured with various shapes depending on a design of the display apparatus 100. For example, the active area AA may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed is larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

Referring to FIG. 3, a plurality of pixel driving circuits PD is disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD includes a power line and a signal line for controlling emission on/off of the micro LED and/or an emission time. For example, the plurality of pixel driving circuits PD may be driving drivers manufactured using a metal-oxide-silicon field effect transistor (MOSFET) manufacturing process on a semiconductor substrate, but the exemplary embodiments of the present disclosure are not limited thereto. The driving driver includes a plurality of pixel driving circuits PD and drives a plurality of sub pixels.

Referring to FIG. 1 together, the flexible circuit board FCB and the printed circuit board 160 may be disposed below the display panel 100. The flexible circuit board FCB and the printed circuit board 160 may be disposed at least at one edge of the display panel 100, but the exemplary embodiments of the present disclosure are not limited thereto. One side of the flexible circuit board FCB is attached to the display panel 100 and the other side is attached to the printed circuit board 160, but the exemplary embodiments of the present disclosure are not limited thereto. The flexible circuit board FCB may be a flexible film, but the exemplary embodiments of the present disclosure are not limited thereto.

A pad unit PAD including a plurality of pad electrodes PE is disposed in the second non-active area NA2. In the pad unit PAD, a driving component including one or more flexible circuit boards (or a flexible films) FCB and the printed circuit boards 160 may be attached or bonded. The plurality of pad electrodes PE of the pad unit PAD is electrically connected to one or more flexible circuit boards (or flexible films) FCB and transmits various signals (or powers) from the printed circuit board 160 and the flexible circuit board (or a flexible film) FCB to the plurality of pixel driving circuits PD of the active area AA.

The flexible circuit board (or flexible film) FCB may be a film on which various components are disposed on a base film having ductility. For example, driving ICs such as a gate driver IC or a data driver IC may be disposed in the flexible circuit board (or flexible film) FCB, but the exemplary embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the exemplary embodiments of the present disclosure are not limited thereto. The flexible circuit board (or flexible film) FCB may be attached or bonded onto the plurality of pad electrodes PE through a conductive adhesive layer, but the exemplary embodiments of the present disclosure are not limited thereto.

The printed circuit board 160 may be a component which is electrically connected to one or more flexible circuit boards (or flexible films) FCB and supplies a signal to the driving IC. The printed circuit board 160 is disposed at one side of the flexible circuit board (or flexible film) FCB to be electrically connected to the flexible circuit board (or flexible film) FCB. On the printed circuit board 160, various components for supplying various signals to the driving IC may be disposed. For example, on the printed circuit board 160, various components, such as a timing controller, a power source, a memory, or a processor, may be disposed. For example, the printed circuit board 160 may include a power management integrated circuit (PMIC), but the exemplary embodiments of the present disclosure are not limited thereto.

The printed circuit board 160 includes at least one hole 180, but the exemplary embodiments of the present disclosure are not limited thereto. An internal component which senses ambient light or temperature to be supplied to a plurality of sensors may be disposed in an area corresponding to at least one hole 180. For example, the internal component may include an ambient light sensor (ALS) or a temperature sensor, but the exemplary embodiments of the present disclosure are not limited thereto. For example, the hole 180 may be a transmission hole, but the exemplary embodiments of the present disclosure are not limited thereto.

Referring to FIG. 1, the polarization layer 293 may be disposed on the display panel 100. The polarization layer 293 may suppress or reduce the influence on the micro led caused by light generated from an external light source and entering the display panel 100.

The cover member 120 may be disposed on the polarization layer 293. The cover member 120 may be a member for protecting the display panel 100. The adhesive layer 295 is disposed between the polarization layer 293 and the cover member 120. The cover member 120 is attached to the display panel 100 using the adhesive layer 295. The adhesive layer 295 may include an optically clear adhesive (OCA), an optically clear resin (OCR), or a pressure sensitive adhesive (PSA), but the exemplary embodiments of the present disclosure are not limited thereto.

The support substrate 170 is disposed between the display panel 100 and the printed circuit board 160. The support substrate 170 may reinforce a rigidity of the display panel 100. The support substrate 170 may be a back plate, but the exemplary embodiments of the present disclosure are not limited thereto.

Referring to FIGS. 1 to 3, the plurality of link lines LL is disposed in the non-active area NA. The plurality of link lines LL is wiring lines which transmit various signals from one or more flexible circuit boards (or flexible films) FCB and the printed circuit board 160 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) FCB and the printed circuit board 160 through the driving line VL of the active area AA and the link line LL of the non-active area NA to be driven.

For example, the plurality of driving lines VL may be wiring lines for transmitting a signal output from the flexible circuit board (or flexible film) FCB and the printed circuit board 160 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) FCB and the printed circuit board 160 is transmitted to each of the plurality of pixel driving circuits PD through the plurality of link lines LL and the plurality of driving lines VL.

As the bending area BA is bent, a part of the plurality of link lines LL is bent together. A stress is concentrated in the bent part of the link line LL, which causes a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the exemplary embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the exemplary embodiments of the present disclosure are not limited thereto.

The plurality of link lines LL may be configured with various shapes to reduce a stress. At least some of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least some of the plurality of link lines LL may be configured by various shapes of patterns. For example, at least some of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the exemplary embodiments of the present disclosure are not limited thereto. Accordingly, in order to minimize or reduce a stress concentrated on the plurality of link lines LL and a crack caused thereby, a shape of the plurality of link lines LL may be various shapes including the above-mentioned shapes, but the exemplary embodiments of the present disclosure are not limited thereto.

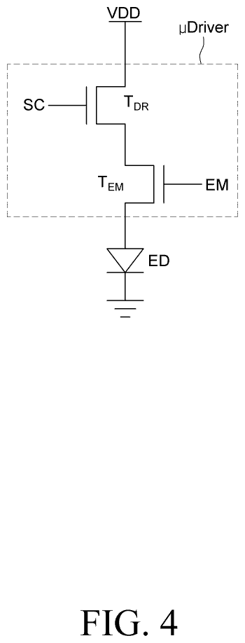

FIG. 4 is a view illustrating a circuit structure according to an exemplary embodiment of the present disclosure.

A pixel driving circuit PD includes a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LEDs (ED) may be simultaneously connected to one micro driver (μDriver).

One micro driver (μDriver) may include a driving transistor T_{DR} and an emission transistor T_{EM}, but the exemplary embodiments of the present disclosure are not limited thereto.

For example, a high potential power voltage VDD is applied to a first electrode of the driving transistor T_{DR} and a first electrode of the emission transistor T_{EM} is connected to a second electrode, and a scan signal SC is applied to a gate electrode. The scan signal SC applied to the gate electrode of the driving transistor T_{DR} is a direct current (DC) power and a fixed reference voltage may be applied in every frame, but the exemplary embodiments of the present disclosure are not limited thereto.

The second electrode of the driving transistor T_{DR} is connected to a first electrode of the emission transistor T_{EM}, the micro LED (ED) is connected to a second electrode, and the emission signal EM is applied to a gate electrode. The emission signal EM applied to the gate electrode of the emission transistor T_{EM} may be a pulse width modulation signal which changes in every frame, but the exemplary embodiments of the present disclosure are not limited thereto.

A first electrode of the micro LED (ED) is connected to the second electrode of the emission transistor T_{EM} and a second electrode is connected to the ground. For example, the first electrode is an anode electrode and the second electrode is a cathode electrode, but the exemplary embodiments of the present disclosure are not limited thereto.

Each of the driving transistor T_{DR} and the emission transistor T_{EM} may be an n type transistor or a p type transistor.

The driving transistor T_{DR} is turned on by a scan signal applied from the timing controller T-CON to the micro driver (μDriver) and the emission transistor T_{EM} is turned on by the emission signal EM. By doing this, the driving current is applied to the micro LED (ED) via the driving transistor T_{DR} and the emission transistor T_{EM} by the high potential power voltage VDD applied to the first electrode of the driving transistor T_{DR} so that the micro LED (ED) emits light.

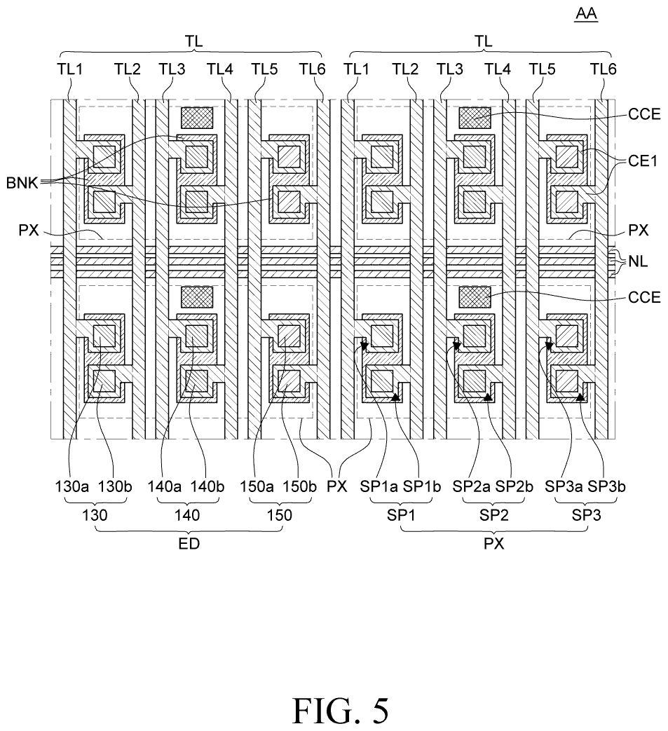

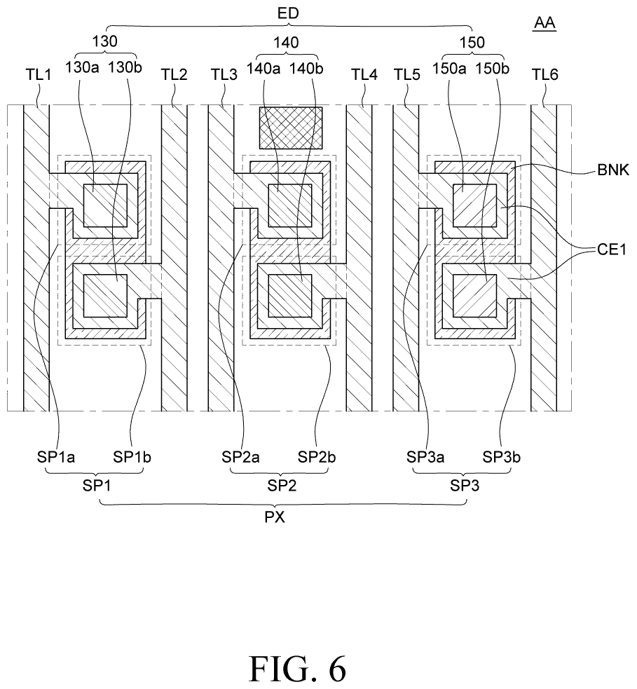

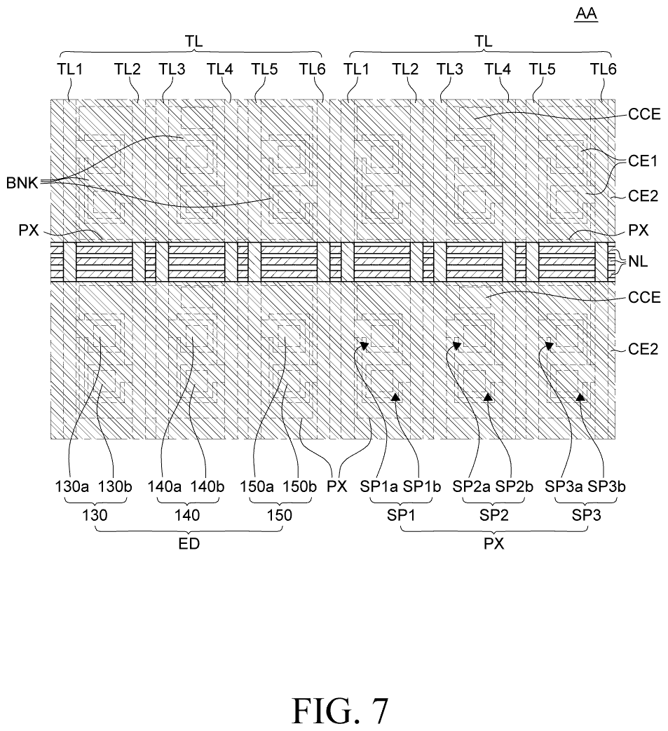

FIGS. 5 to 7 are plan views of a display apparatus according to an exemplary embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, only a plurality of signal lines TL, a plurality of communication lines NL, a plurality of first electrodes CE1, a plurality of banks BNK, and a plurality of micro LEDs (ED) are illustrated, but the exemplary embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which is configured by a plurality of sub pixels is disposed in the active area AA. Each of the plurality of sub pixels includes a micro LED (ED) and independently emits light. The plurality of sub pixels may be disposed in a matrix by forming a plurality of rows and a plurality of columns, but the exemplary embodiments of the present disclosure are not limited thereto.

The plurality of sub pixels includes a first sub pixel SP1, a second sub pixel SP2, and a third sub pixel SP3. For example, any one of the first sub pixel SP1, the second sub pixel SP2, and the third sub pixel SP3 is a red sub pixel, another is a green sub pixel, and the third is a blue sub pixel. The types of the plurality of sub pixels are illustrative, but the exemplary embodiments of the present disclosure are not limited thereto.

Each of the plurality of pixels PX includes one or more first sub pixels SP1, one or more second sub pixels SP2, and one or more third sub pixels SP3. For example, one pixel PX includes one pair of first sub pixels SP1, one pair of second sub pixels SP2, and one pair of third sub pixels SP3. One pair of first sub pixels SP1 is configured by a 1-1-th sub pixel SP1a and a 1-2-th sub pixel SP1b. One pair of second sub pixels SP2 is configured by a 2-1-th sub pixel SP2a and a 2-2-th sub pixel SP2b. One pair of third sub pixels SP3 is configured by a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the exemplary embodiments of the present disclosure are not limited thereto.

The plurality of sub pixels which forms one pixel PX may be disposed in various ways. For example, in one pixel PX, one pair of first sub pixels SP1 may be disposed on the same column, one pair of second sub pixels SP2 may be disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the exemplary embodiments of the present disclosure are not limited thereto.

The plurality of signal lines TL is disposed in an area between the plurality of sub pixels. The plurality of signal lines TL extends in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD is transmitted to the first electrode CE1 of the plurality of sub pixels through the plurality of signal lines TL. For example, the first electrode CE1 is an electrode which is electrically connected to the anode electrode 134 of the micro LED (ED). Therefore, the anode voltage from the signal line TL is transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving is possible.

The plurality of signal lines TL includes a first signal line TL1, a second signal line TL2, a third signal line TL3, a fourth signal line TL4, a fifth signal line TL5, and a sixth signal line TL6. The first signal line TL1 and the second signal line TL2 are electrically connected to one pair of first sub pixels SP1, respectively. The third signal line TL3 and the fourth signal line TL4 are electrically connected to one pair of second sub pixels SP2, respectively. The fifth signal line TL5 and the sixth signal line TL6 are electrically connected to one pair of third sub pixels SP3, respectively.

The first signal line TL1 is disposed on one of one pair of first sub pixels SP1 and the second signal line TL2 is disposed on the other one of one pair of first sub pixels SP1. The first signal line TL1 is electrically connected to one first sub pixel SP1, between one pair of first sub pixels SP1, for example, to the first electrode CE1 of the 1-1-th sub pixel SP1a. The second signal line TL2 is electrically connected to the other first sub pixel SP1, between one pair of first sub pixels SP1, for example, to the first electrode CE1 of the 1-2-th sub pixel SP1b.

The third signal line TL3 is disposed on one of one pair of second sub pixels SP2 and the fourth signal line TL4 is disposed on the other one of one pair of second sub pixels SP2. For example, the third signal line TL3 is disposed to be adjacent to the second signal line TL2. The third signal line TL3 is electrically connected to one second sub pixel SP2, between one pair of second sub pixels SP2, for example, to the first electrode CE1 of the 2-1-th sub pixel SP2a. The fourth signal line TL4 is electrically connected to the other second sub pixel SP2, between one pair of second sub pixels SP2, for example, to the first electrode CE1 of the 2-2-th sub pixel SP2b.

The fifth signal line TL5 is disposed on one of one pair of third sub pixels SP3 and the sixth signal line TL6 is disposed on the other one of one pair of third sub pixels SP3. For example, the fifth signal line TL5 is disposed to be adjacent to the fourth signal line TL4. The sixth signal line TL6 is disposed to be adjacent to the first signal line TL1 connected to the adjacent pixel PX. The fifth signal line TL5 is electrically connected to one third sub pixel SP3, between one pair of third sub pixels SP3, for example, to the first electrode CE1 of the 3-1-th sub pixel SP3a. The sixth signal line TL6 is electrically connected to the other third sub pixel SP3, between one pair of third sub pixels SP3, for example, to the first electrode CE1 of the 3-2-th sub pixel SP3b.

The plurality of signal lines TL may be formed of a conductive material. For example, the plurality of signal lines TL is configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL is formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL is disposed in an area between the plurality of pixels PX. The plurality of communication lines NL is disposed to extend in the row direction in an area between the plurality of pixels PX. The plurality of communication lines NL is disposed in the area between the plurality of second electrodes CE2 and does not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the exemplary embodiments of the present disclosure are not limited thereto.

According to the present disclosure, a bank BNK is disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display apparatus 1000. The plurality of micro LEDs (ED) is transferred onto the plurality of banks BNK in the transfer process of the plurality of micro LEDs (ED). The plurality of banks BNK may be a bank pattern or a structure, but the exemplary embodiments of the present disclosure are not limited thereto.

A bank BNK of the first sub pixel SP1, a bank BNK of the second sub pixel SP2, and a bank BNK of the third sub pixel SP3 are disposed to be spaced apart from each other. The bank BNK of the first sub pixel SP1, the bank BNK of the second sub pixel SP2, and the bank BNK of the third sub pixel SP3 are configured to be separated from each other. Therefore, the banks BNK of the first sub pixel SP1, the second sub pixel SP2, and the third sub pixel SP3 to which different types of micro LEDs (ED) are transferred may be easily identified.

The bank BNK of the 1-1-th sub pixel SP1a and the bank BNK of the 1-2-th sub pixel SP1b are connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed may be connected to each other or spaced apart or separated from each other. The bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of one pair of third sub pixels SP3 are formed in various forms, but the exemplary embodiments of the present disclosure are not limited thereto.

For example, the plurality of banks BNK may be formed of an organic insulating material. The plurality of banks BNK is configured by a single layer or a double layer of an organic insulating material. For example, the plurality of banks BNK is configured by a photo resist, polyimide (PI), or acrylic material, but the exemplary embodiments of the present disclosure are not limited thereto.

The first electrode CE1 is disposed in each of the plurality of sub pixels. The first electrode CE1 is disposed on the bank BNK. The first electrode CE1 is electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 is electrically connected to the anode electrode 134 of the micro LED (ED) and transmits an anode voltage from the pixel driving circuit PD to the micro LED (ED) through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the exemplary embodiments of the present disclosure are not limited thereto.

The first electrode CE1 is configured by a conductive material. For example, the first electrode CE1 is integrally configured with the plurality of signal lines TL. For example, the first electrode CE1 is configured by the same conductive material as the plurality of signal lines TL, but the exemplary embodiments of the present disclosure are not limited thereto. For example, the first electrode CE1 is configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 is configured by a multi-layered structure of conductive materials. For example, the plurality of first electrodes CE1 is configured by a multi-layered structure of titanium (Ti)/aluminum (Al)/titanium (Ti)/indium tin oxide (ITO), but the exemplary embodiments of the present disclosure are not limited thereto.

The micro LED (ED) is disposed in each of the plurality of sub pixels. The plurality of micro LEDs (ED) may be any one of a light-emitting diode or a micro light-emitting diode (micro LED), but the exemplary embodiments of the present disclosure are not limited thereto. The plurality of micro LEDs (ED) is disposed on the bank BNK and the first electrode CE1. The plurality of micro LEDs (ED) is disposed on the first electrode CE1 and is electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) includes a first micro LED 130, a second micro LED 140, and a third micro LED 150. The first micro LED 130 is disposed in the first sub pixel SP1. The second micro LED 140 is disposed in the second sub pixel SP2. The third micro LED 150 is disposed in the third sub pixel SP3. For example, any one of the first micro LED 130, the second micro LED 140, and the third micro LED 150 is a red micro LED, another is a green micro LED, and the third is a blue micro LED, but the exemplary embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the exemplary embodiments of the present disclosure are not limited thereto.

The first micro LED 130 includes a 1-1-th micro LED 130a disposed in the 1-1-th sub pixel SP1a and a 1-2-th micro LED 130b disposed in the 1-2-th sub pixel SP1b. The second micro LED 140 includes a 2-1-th micro LED 140a disposed in the 2-1-th sub pixel SP2a and a 2-2-th micro LED 140b disposed in the 2-2-th sub pixel SP2b. The third micro LED 150 includes a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 is disposed in each of the plurality of sub pixels. The second electrode CE2 is disposed on the micro LED (ED). The second electrode CE2 is electrically connected to the pixel driving circuit PD through a plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage may be applied to the second electrode CE2 of each of the plurality of sub pixels and the cathode electrode 135 of the micro LED (ED). Therefore, the second electrode CE2 may be a common electrode, but the exemplary embodiments of the present disclosure are not limited thereto.

At least some of the plurality of sub pixel shares the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes CE2 of at least some pixels PX, among the plurality of pixels PX disposed on the same row, are connected to each other. For example, one second electrode CE2 may be disposed in the plurality of pixels PX. One second electrode CE2 may be disposed in every n sub pixels.

For example, some of the second electrodes CE2 of the plurality of sub pixels is spaced apart or separated from each other. For example, a second electrode CE2 connected to pixels PX in a n-th row and a second electrode CE2 connected to pixels PX in a n+1-th row are spaced apart or separated from each other. For example, the plurality of second electrodes CE2 is spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 is disposed on the substrate 110, but the exemplary embodiments of the present disclosure are not limited thereto.

The plurality of second electrodes CE2 may be configured by a transparent conductive material, but the exemplary embodiments of the present disclosure are not limited thereto. The plurality of second electrodes CE2 is configured by a transparent conductive material so that light emitted from the micro LED (ED) travels toward the top of the second electrode CE2. For example, the second electrode CE2 is configured by a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE is disposed on the substrate 110. For example, the plurality of contact electrodes CCE is disposed to be spaced apart from the plurality of banks BNK and the plurality of signal lines TL. Each of the plurality of second electrodes CE2 overlaps at least one contact electrode CCE. For example, one second electrode CE2 overlaps a plurality of contact electrodes CCE.

For example, the plurality of contact electrodes CCE is electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

For example, when a micro LED (ED) is used as the LED, a plurality of micro LEDs is formed on a wafer and the micro LED is transferred onto the substrate 110 of the display apparatus 1000 to manufacture the display apparatus 1000. However, during the process of transferring the plurality of micro LEDs (ED) having a micro size from the wafer to the substrate 110, various defects may be caused. For example, in some sub pixel, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) may be defective. Accordingly, in consideration of the defects during the transfer process of the plurality of micro LEDs (ED), a plurality of same type micro LEDs may be transferred in one sub pixel. A lighting test for the plurality of micro LEDs (ED) is performed and only one micro LED (ED) which is finally determined to be normal may be used.

For example, the 1-1-th micro LED 130a and the 1-2-th micro LED 130b are transferred to one pixel PX together and defects thereof are tested. If both the 1-1-th micro LED 130a and the 1-2-th micro LED 130b are determined to be normal, only the 1-1-th micro LED 130a is used, but the 1-2-th micro LED 130b is not used. As another example, if only the 1-2-th micro LED 130b between the 1-1-th micro LED 130a and the 1-2-th micro LED 130b is determined to be normal, the 1-1-th micro LED 130a is not used, but only the 1-2-th micro LED 130b is used. Accordingly, even though the plurality of same type micro LEDs (ED) is transferred to one pixel PX, finally, only one micro LED (ED) is used.

Therefore, any one of one pair of micro LEDs (ED) is a main (or primary) micro LED (ED) and the other micro LED ED) is a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized or reduced.

For example, a 1-1-th micro LED 130a, a 2-1-th micro LED 140a, and a 3-1-th micro LED 150a which are transferred into one pixel PX are used as main micro LEDs (ED) and a 1-2-th micro LED 130b, a 2-2-th micro LED 140b, and a 3-2-th micro LED 150b are used as redundancy micro LEDs (ED).

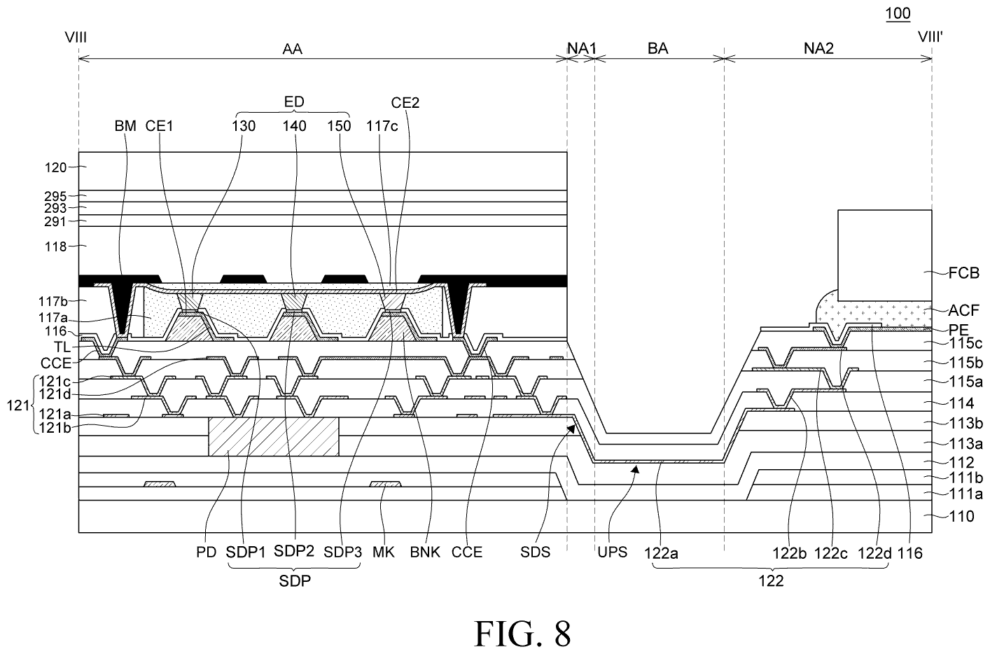

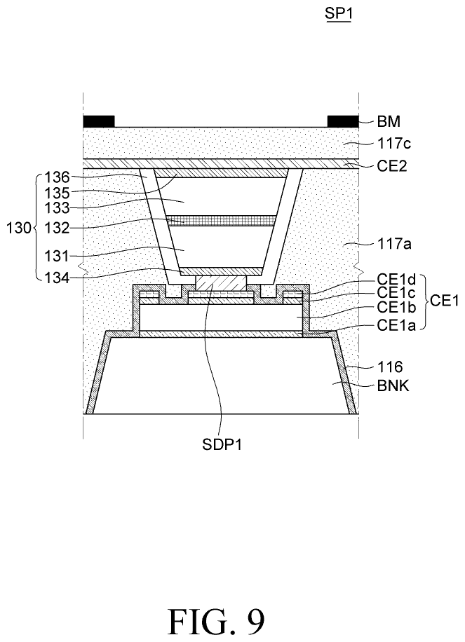

FIG. 8 is a cross-sectional view taken along VIII-VIII′ of FIG. 3. FIG. 9 is a cross-sectional view of a display apparatus according to an exemplary embodiment of the present disclosure; FIG. 8 is a cross-sectional view of a display apparatus according to an exemplary embodiment of the present disclosure. For example, FIG. 8 is a cross-sectional view of an active area AA, a first non-active area NA1, a bending area BA, and a second non-active area NA2. For example, FIG. 9 is an enlarged cross-sectional view of a first sub pixel. In the meantime, for the convenience of illustration, in FIG. 3, it is illustrated that a cross-sectional line of VIII-VIII′ and a driving line VL and a link line LL do not overlap, but the cross-sectional line VIII-VIII′ of FIG. 3 is provided to represent the same position as the adjacent driving line VL and link line LL.

Referring to FIG. 8, a first buffer layer 111a and a second buffer layer 111b are disposed in the remaining area of the substrate 110 excluding the bending area BA.

The first buffer layer 111a and the second buffer layer 111b are disposed in the active area AA, the first non-active area NA1, and the second non-active area NA2. The first buffer layer 111a and the second buffer layer 411b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOx) or silicon nitride (SiNx), but the exemplary embodiments of the present disclosure are not limited thereto.

For example, the first buffer layer 111a and the second buffer layer 111b on the bending area BA may be partially removed. An upper surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display apparatus 1000. For example, the plurality of alignment keys MK may be configured to align a position of the pixel driving circuit PD which is transferred onto the adhesive layer 112. As another example, the plurality of alignment keys MK may be reduced or omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD is disposed on the adhesive layer 112 in the active area AA. When the pixel driving circuit PD is implemented as a driving driver, the driving driver may be mounted on the adhesive layer 112 by the transfer process, but the exemplary embodiments of the present disclosure are not limited thereto.

A first protection layer 113a and a second protection layer 113b are disposed on the adhesive layer 112 and the pixel driving circuit PD. For example, the first protection layer 113a and the second protection layer 113b are disposed so as to enclose the side surface of the pixel driving circuit PD, but the exemplary embodiments of the present disclosure are not limited thereto. For example, the second protection layer 113b may be disposed so as to cover at least a part of an upper surface of the pixel driving circuit PD. For example, at least one of the first protection layer 113a and the second protection layer 113b of the protection layer 113 disposed on the bending area BA may be omitted. For example, the first protection layer 113a is entirely disposed in the active area AA and the non-active area NA and the second protection layer 113b is partially disposed in the active area AA, the first non-active area NA1, and the second non-active area NA2. For example, a part of the second protection layer 113b in the bending area BA may be removed, but the exemplary embodiments of the present disclosure are not limited thereto.

The first protection layer 113a and the second protection layer 113b may be configured by an organic insulating material, but the exemplary embodiments of the present disclosure are not limited thereto. For example, the first protection layer 113a and the second protection layer 113b are configured by a photo resist, polyimide (PI), or photo acrylic material, but the exemplary embodiments of the present disclosure are not limited thereto. For example, the first protection layer 113a and the second protection layer 113b may be over coating layers or insulating layers, but the exemplary embodiments of the present disclosure are not limited thereto.

According to the present specification, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121b, but the exemplary embodiments of the present disclosure are not limited thereto.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CE1 or the second electrode CE2.

For example, a third protection layer 114 may be disposed on the second protection layer 113b. The third protection layer 114 is entirely disposed in the active area AA and the non-active area NA. In the bending area BA, the third protection layer 114 may cover a side surface SDS of the second protection layer 113b and the upper surface UPS of the first protection layer 113a. The third protection layer 114 may be configured by an organic insulating material. For example, the third protection layer 114 is configured by a photo resist, polyimide (PI), or photo acrylic material, but the exemplary embodiments of the present disclosure are not limited thereto. For example, the first protection layer 113a, the second protection layer 113b, and the third protection layer 114 may be configured by the same material, but the exemplary embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b is electrically connected to the 1-1-th connection line 121a through the contact hole of the third protection layer 114, but the exemplary embodiments of the present disclosure are not limited thereto. A voltage output from the pixel driving circuit PD is transmitted to the first electrode CE1 or the second electrode CE2 through a connection line other than the plurality of 1-2-th connection lines 121b.

The first insulating layer 115a is disposed on the plurality of 1-2-th connection lines 121b. The first insulating layer 115a is entirely disposed in the active area AA and the non-active area NA, but the exemplary embodiments of the present disclosure are not limited thereto. The first insulating layer 115a is configured by an organic insulating material, but the exemplary embodiments of the present disclosure are not limited thereto. For example, the first insulating layer 115a is configured by a photo resist, polyimide (PI), or photo acrylic material, but the exemplary embodiments of the present disclosure are not limited thereto.

The plurality of 1-3-th connection lines 121c may be disposed on the first insulating layer 115a. The plurality of 1-3-th connection lines 121c is electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b is disposed on the plurality of 1-3-th connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b is configured by an organic insulating material, but the exemplary embodiments of the present disclosure are not limited thereto. For example, the second insulating layer 115b is configured by a photo resist, polyimide (PI), or photo acrylic material, but the exemplary embodiments of the present disclosure are not limited thereto.

The plurality of 1-4-th connection lines 121d may be disposed on the second insulating layer 115b. The plurality of 1-4-th connection lines 121d is electrically connected to the plurality of 1-3-th connection lines 121c. For example, the 1-4-th connection lines 121d may be electrically connected to the 1-3-th connection line 121c through a contact hole of the second insulating layer 115b.

According to the present specification, in the non-active area NA, the plurality of second connection lines 122 may be disposed on the second protection layer 113b. The plurality of second connection lines 122 may be wiring lines which transmit a signal transmitted from the flexible circuit board (or flexible film) FCB and the printed circuit board 160 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) FCB and the printed circuit board.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 includes a 2-1-th connection line 122a, a 2-2-th connection line 122b, a 2-3-th connection line 122c, and a 2-4-th connection line 122d.

The plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) FCB and the printed circuit board 160 to the pad unit PAD to the pixel driving circuit PD of the active area AA. For example, the 2-1-th connection line 122a extends from the second non-active area NA2 to the first non-active area NA1 and is electrically connected to any one of the 1-1-th connection line 121a, the 1-2-th connection line 121b, the 1-3-th connection line 121c, and the 1-4-th connection line 121d of the plurality of first connection lines 121. For example, the 2-1-th connection line 122a may be directly connected to the 1-1-th connection line 121a disposed on the same layer or may be connected to the 1-2-th connection line 121b disposed on a different layer through a contact hole of the third protection layer 114, but is not limited thereto.

The plurality of 2-2-th connection lines 122b may be disposed on the third protection layer 114. The plurality of 2-2-th connection lines 122b may be disposed in the second non-active area NA2. The 2-2-th connection line 122b is electrically connected to the 2-1-th connection line 122a through the contact hole of the third protection layer 114. Accordingly, a signal from the flexible circuit board (or flexible film) FCB and the printed circuit board may be transmitted to the 2-1-th connection line 122a through the 2-2-th connection line 122b.

The 2-3-th connection line 122c may be disposed on the first insulating layer 115a. The 2-3-th connection lines 122c may be disposed in the second non-active area NA2. The 2-3-th connection line 122c may be electrically connected to the 2-2-th connection line 122b through a contact hole of the first insulating layer 115a. Accordingly, a signal from the flexible circuit board (or flexible film) FCB and the printed circuit board may be transmitted to the 2-1-th connection line 122a through the 2-3-th connection line 122c and the 2-2-th connection line 122b.

The 2-4-th connection line 122d may be disposed on the second insulating layer 115b. The 2-4-th connection line 122d may be disposed in the second non-active area NA2. The 2-4-th connection line 122d may be electrically connected to the 2-3-th connection line 122c through a contact hole of the second insulating layer 115b. Accordingly, a signal from the flexible circuit board (or flexible film) FCB and the printed circuit board 160 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the exemplary embodiments of the present disclosure are not limited thereto. The third insulating layer 115c is disposed in the active area AA, the first non-active area NA1, and the second non-active area NA2. A part of the third insulating layer 115c disposed in the bending area BA may be removed. The third insulating layer 115c is configured by an organic insulating material, but the exemplary embodiments of the present disclosure are not limited thereto. For example, the third insulating layer 115c is configured by a photo resist, polyimide (PI), or photo acrylic material, but the exemplary embodiments of the present disclosure are not limited thereto.

A plurality of banks BNK is disposed on the third insulating layer 115c in the active area AA. The plurality of banks BNK is disposed so as to overlap each of the plurality of sub pixels. One or more same type micro LED (ED) may be disposed above each of the plurality of banks BNK.

A plurality of signal lines TL is disposed on the third insulating layer 115c in the active area AA. The plurality of signal lines TL is disposed in an area between the plurality of banks BNK. For example, the plurality of signal lines TL is disposed to be adjacent to any one of the plurality of banks BNK.

A plurality of contact electrodes CCE is disposed on the third insulating layer 115c in the active area AA. The plurality of contact electrodes CCE supplies a cathode voltage from the pixel driving circuit PD to the second electrode CE2.

The first electrode CE1 is disposed on the bank BNK. For example, the first electrode CE1 is disposed to extend toward the top of the bank BNK from the adjacent signal line TL. The first electrode CE1 is disposed on the upper surface of the bank BNK and the side surface of the bank BNK. For example, the first electrode CE1 is disposed to extend from the signal line TL on the upper surface of the third insulating layer 115c to the side surface of the bank BNK and the upper surface of the bank BNK.

Referring to FIG. 9, the first electrode CE1 is configured by a plurality of conductive layers. For example, the first electrode CE1 includes a first conductive layer CE1a, a second conductive layer CE1b, a third conductive layer CE1c, and a fourth conductive layer CE1d, but the exemplary embodiments of the present disclosure are not limited thereto.

The first conductive layer CE1a is disposed on the bank BNK. The second conductive layer CE1b is disposed on the first conductive layer CE1a. The third conductive layer CE1c is disposed on the second conductive layer CE1b. The fourth conductive layer CE1d is disposed on the third conductive layer CE1c. For example, the first conductive layer CE1a, the second conductive layer CE1b, the third conductive layer CE1c, and the fourth conductive layer CE1d are configured by titanium (Ti), molybdenum (Mo), aluminum (Al), or titanium (Ti) and indium tin oxide (ITO), but the exemplary embodiments of the present disclosure are not limited thereto.

According to the present disclosure, some conductive layer having a good reflection efficiency, among a plurality of conductive layers which configures the first electrode CE1, may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED (ED) or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose an upper surface of the second conductive layer CE1b. For example, a center portion and an edge portion (or a boundary portion) of the third conductive layer CE1c and the fourth conductive layer CE1d in which a solder pattern SDP is disposed remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c include titanium (Ti) or molybdenum (Mo). The second conductive layer CE1b includes aluminum (Al). The fourth conductive layer CE1d includes a transparent conductive oxide layer, such as indium tin oxide (ITO) or indium zinc oxide (IZO), which is adhesive to the solder pattern SPD, and has anti-corrosion and acid resistance, but the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithography process and an etching process to be patterned. However, the exemplary embodiments of the present disclosure are not limited thereto.

According to the present specification, the signal line TL, the contact electrode CCE, and the pad electrode PE disposed on the same layer as the first electrode CE1 may be configured by multiple layers of conductive materials, but the exemplary embodiments of the present disclosure are not limited thereto. For example, the signal line TL, the contact electrode CCE, and the pad electrode PE may be formed of multiple layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, a solder pattern SDP is disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) may be electrically connected through eutectic bonding using the solder pattern SDP, but the exemplary embodiments of the present disclosure are not limited thereto.

For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) is bonded to the solder pattern SDP and the first electrode CE1 using the eutectic bonding without a separate adhesive material. For example, the solder pattern SDP may be configured by indium (Id), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto.

The plurality of solder patterns SDP includes a first solder pattern SDP1 disposed in the first sub pixel SP1, a second solder pattern SDP2 disposed in the second sub pixel SP2, and a third solder pattern SDP3 disposed in the third sub pixel SP3.

According to the present specification, the passivation layer 116 is disposed on the plurality of signal lines TL, the plurality of first electrodes CE1, the plurality of contact electrodes CCE, and the third insulating layer 115c. For example, the passivation layer 116 is disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may be configured by a single layer or multiple layers of silicon oxide (SiOx) or silicon nitride (SiNx), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole through which the solder pattern SDP is exposed.

In each of the plurality of sub pixels, the micro LED (ED) is disposed on the solder pattern SDP. A first micro LED 130 is disposed in the first sub pixel SP1. A second micro LED 140 is disposed in the second sub pixel SP2. A third micro LED 150 is disposed in the third sub pixel SP3.

The micro LED (ED) is formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 9, the first micro LED 130 includes an anode electrode 134, a first semiconductor layer 131, an active layer 132, a second semiconductor layer 133, a cathode electrode 135, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 is disposed on the first semiconductor layer 131.

For example, one of the first semiconductor layer 131 and the second semiconductor layer 133 may be implemented by a compound semiconductor, such as a III-V group or a II-VI group and is doped with an impurity (or dopant). For example, one of the first semiconductor layer 131 and the second semiconductor layer 133 is an n-type impurity doped semiconductor layer and the other one is a p-type impurity doped semiconductor, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Se), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each the first semiconductor layer 131 and the second semiconductor layer 133 is a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 is disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by any one of a single well structure, a multi-well structure, a signal quantum well structure, a multi-quantum well (MQC) structure, a quantum dot structure, and a quantum line structure, but the exemplary embodiments of the present disclosure are not limited thereto. For example, the active layer 132 may be configured by indium gallium nitride (InGaN) or gallium nitride (GaN), but the exemplary embodiments of the present disclosure are not limited thereto.

As another example, the active layer 132 has a multi quantum well (MQW) structure having a well layer and a barrier layer with a band gap higher than the well layer. For example, in the active layer 132, InGaN is configured as a well layer and an AlGaN layer is configured as a barrier layer, but the exemplary embodiments of the present disclosure are not limited thereto.

The anode electrode 134 is disposed between the first semiconductor layer 131 and the solder pattern SDP. For example, the anode electrode 134 electrically connects the first semiconductor layer 131 and the first electrode CE1. The anode voltage output from the pixel driving circuit PD is applied to the first semiconductor layer 131 through the signal line TL, the first electrode CE1, and the anode electrode 134. For example, the anode electrode 134 may be configured by a conductive material which may form eutectic bonding with the solder pattern SDP, but the exemplary embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 is disposed on the second semiconductor layer 133. For example, the cathode electrode 135 electrically connects the second semiconductor layer 133 and the second electrode CE2. A cathode voltage output from the pixel driving circuit PD is applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the exemplary embodiments of the present disclosure are not limited thereto. For example, the cathode electrode 135 is configured by a material, such as indium tin oxide (ITO), indium zinc oxide (IZO), or indium gallium zinc oxide (IGZO), but the exemplary embodiments of the present disclosure are not limited thereto.

The encapsulation film 136 is disposed in at least a part of the first semiconductor layer 131, the active layer 132, the second semiconductor layer 133, the anode electrode 134, and the cathode electrode 135. For example, the encapsulation film 136 encloses at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 is disposed on a side surface of the first semiconductor layer 131, a side surface of the active layer 132, and a side surface of the second semiconductor layer 133.

For example, the encapsulation film 136 is disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP are connected. For example, at least a part of the cathode electrode 135 is exposed from the encapsulation film 136 so that the cathode electrode 135 and the second electrode CE2 are connected. For example, the encapsulation film 136 is formed of an insulating material, such as silicon nitride (SiNx) or silicon oxide (SiOx), but the exemplary embodiments of the present disclosure are not limited thereto.

As another example, the encapsulation film 136 has a structure in which a reflective material is dispersed in a resin layer, but the exemplary embodiments of the present disclosure are not limited thereto. For example, the encapsulation film 136 is manufactured with reflectors with various structures, but the exemplary embodiments of the present disclosure are not limited thereto. Light emitted from the active layer 132 is upwardly reflected by the encapsulation film 136 so that light extraction efficiency is improved. For example, the encapsulation film 136 may be a reflective layer, but the exemplary embodiments of the present disclosure are not limited thereto.

According to the present specification, it is described that the micro LED (ED) has a vertical structure, but the exemplary embodiments of the present disclosure are not limited thereto. For example, the micro LED (ED) may have a lateral structure or a flip-chip structure.

The first micro LED 130 has been described with reference to FIG. 9 and the second micro LED 140 and the third micro LED 150 may have the substantially same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present specification, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a first row direction and is spaced apart from each other in a second column direction. For example, the first optical layer 117a is disposed so as to enclose side portions of the micro LED (ED) and the bank BNK between the passivation layer 116 and the second electrode CE2, but the exemplary embodiments of the present disclosure are not limited thereto. For example, the first optical layer 117a may be a diffusion layer or a side wall diffusion layer, but the exemplary embodiments of the present disclosure are not limited thereto.

The first optical layer 117a includes an organic insulating material in which micro particles are dispersed, but the exemplary embodiments of the present disclosure are not limited thereto. For example, the first optical layer 117a may be configured by siloxane in which micro metal particles, such as titanium dioxide (TiO₂) particles, are dispersed, but the exemplary embodiments of the present disclosure are not limited thereto. Light from the plurality of micro LEDs (ED) is scattered by micro particles dispersed in the first optical layer 117a to be emitted to the outside of the display apparatus 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the exemplary embodiments of the present disclosure are not limited thereto. For example, the first optical layer 117a is disposed in each of the plurality of pixels PX or the plurality of pixels PX may share one first optical layer 117a. As another example, each of the plurality of sub pixels separately includes the first optical layer 117a, but the exemplary embodiments of the present disclosure are not limited thereto.

According to the present disclosure, in the active area AA, a second optical layer 117b is disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the exemplary embodiments of the present disclosure are not limited thereto. For example, the second optical layer 117b may be a diffusion layer, a diffusion window, or a window diffusion layer, but the exemplary embodiments of the present disclosure are not limited thereto.

The second optical layer 117b is configured by an organic insulating material, but the exemplary embodiments of the present disclosure are not limited thereto. The second optical layer 117b is configured by the same material as the first optical layer 117a, but the exemplary embodiments of the present disclosure are not limited thereto. For example, the first optical layer 117a may include micro particles, but the second optical layer 117b does not include micro particles. For example, the second optical layer 117b is configured by siloxane, but the exemplary embodiments of the present disclosure are not limited thereto.

For example, a thickness of the first optical layer 117a may be smaller than a thickness of the second optical layer 117b, but the exemplary embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 is disposed on the plurality of micro LEDs (ED). For example, the second electrode CE2 includes a transparent conductive oxide, such as indium tin oxide (ITO) or indium zinc oxide (IZO), but the exemplary embodiments of the present disclosure are not limited thereto. For example, the second electrode CE2 is disposed to be in contact with the cathode electrode 135. For example, the second electrode CE2 overlaps the first optical layer 117a. For example, the second electrode may cover a plane of the outside of the first optical layer 117a.

The second electrode CE2 continuously extends in a first direction of the substrate 110. Accordingly, the second electrode CE2 may be commonly connected to the plurality of pixels PX disposed in the first direction of the substrate 110. For example, the second electrode CE2 is commonly connected to the plurality of pixels PX.

According to the present specification, the second electrode CE2 continuously extends on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c is disposed on the second electrode CE2. The third optical layer 117c is disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be improved. For example, when the plurality of micro LEDs (ED) is transferred onto the substrate 110 of the display apparatus 1000, an area in which the interval between the plurality of micro LEDs (ED) is not uniform may be caused due to a process deviation. When the interval between the plurality of micro LEDs (ED) is not uniform, an emission area of each of the plurality of micro LEDs (ED) is not uniformly disposed so that the spot (mura) may be visible to a user. Accordingly, the third optical layer 117c which is configured to uniformly diffuse light is configured above the plurality of micro LEDs (ED) so that light emitted from some micro LED (ED) which is visible as spots may be reduced. Accordingly, light emitted from the plurality of micro LEDs (ED) is uniformly diffused by the third optical layer 117c to be extracted to the outside of the display apparatus 1000 so that the luminance uniformity of the display apparatus 1000 may be improved.

The third optical layer 117c is configured by an organic insulating material in which micro particles are dispersed, but the exemplary embodiments of the present disclosure are not limited thereto. For example, the third optical layer 117c may be configured by siloxane in which micro metal particles, such as titanium dioxide (TiO₂) particles, are dispersed, but the exemplary embodiments of the present disclosure are not limited thereto. For example, the third optical layer 117c is configured by the same material as the first optical layer 117a, but the exemplary embodiments of the present disclosure are not limited thereto. For example, the third optical layer 117c may be a diffusion layer or an upward diffusion layer, but the exemplary embodiments of the present disclosure are not limited thereto.

According to the present specification, light from the plurality of micro LEDs (ED) is scattered by micro particles dispersed in the third optical layer 117c to be emitted to the outside of the display apparatus 1000. The third optical layer 117c uniformly mixes light emitted from the plurality of micro LEDs (ED) to further improve the luminance uniformity of the display apparatus 1000. The light extraction efficiency of the display apparatus 1000 may be improved by light scattered from the plurality of micro particles so that the display apparatus 1000 may be driven at a low power.

In the active area AA, a black matrix BM is disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels is suppressed.

For example, the black matrix BM may be configured by an opaque material, but the exemplary embodiments of the present disclosure are not limited thereto. For example, the black matrix BM may be configured by an organic insulating material to which black pigment or black dye is added, but the exemplary embodiments of the present disclosure are not limited thereto.

In the active area AA, a cover layer 118 is disposed on the black matrix BM. The cover layer 118 protects configurations below the cover layer 118. For example, the cover layer 118 is configured by an organic insulating material, but the exemplary embodiments of the present disclosure are not limited thereto. For example, the cover layer 118 is configured by a photo resist, polyimide (PI), or photo acrylic material, but the exemplary embodiments of the present disclosure are not limited thereto. For example, the cover layer 118 may be an over coating layer or an insulating layer, but the exemplary embodiments of the present disclosure are not limited thereto.

A polarization layer 293 is disposed on the cover layer 118 by means of the first adhesive layer 291. A cover member 120 is disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present specification, a plurality of pad electrodes PE is disposed on the third insulating layer 115c in the second non-active area NA2. For example, at least some of the plurality of pad electrodes PE may be exposed from the passivation layer 116. For example, the plurality of pad electrodes PE may be electrically connected to the 2-4-th connection line 122d through a contact hole of the third insulating layer 115c.

The adhesive layer ACF is disposed on the plurality of pad electrodes PE. The adhesive layer ACF may be an adhesive layer in which conductive balls are dispersed in an insulating material, but the exemplary embodiments of the present disclosure are not limited thereto. When heat or a pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) FCB so that the flexible circuit board (or flexible film) FCB may be attached or bonded to the plurality of pad electrodes PE. For example, the adhesive layer ACF may be anisotropic conductive film, but the exemplary embodiments of the present disclosure are not limited thereto.

The flexible circuit board (or flexible film) FCB is disposed on the adhesive layer ACF. The flexible circuit board (or flexible film) FCB may be electrically connected to the plurality of pad electrodes PE through the adhesive layer ACF. Accordingly, a signal output from the flexible circuit board (or flexible film) FCB and the printed circuit board 160 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

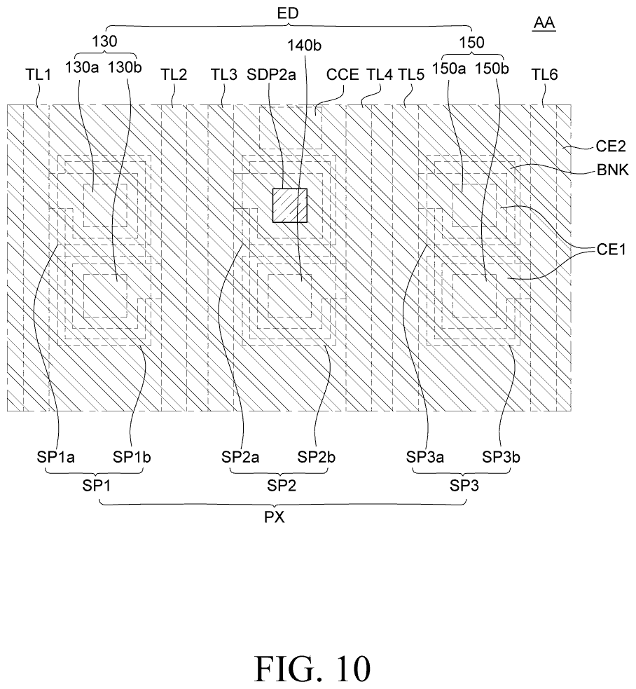

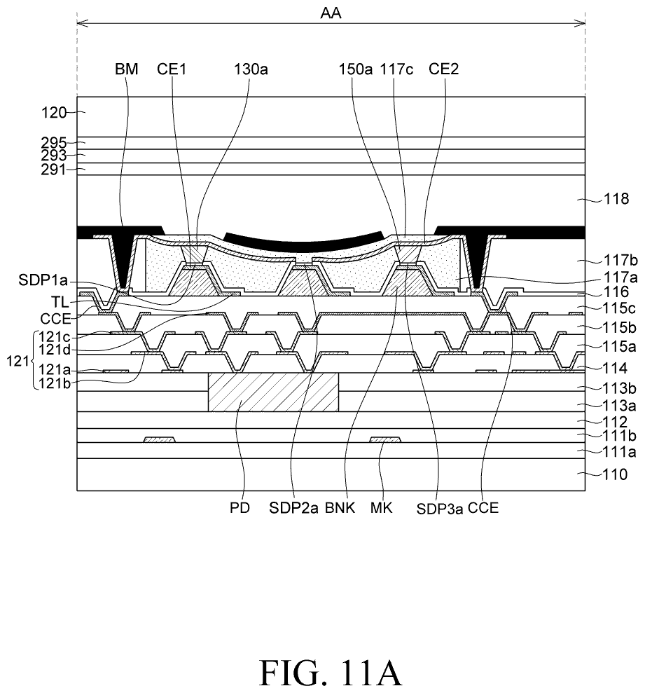

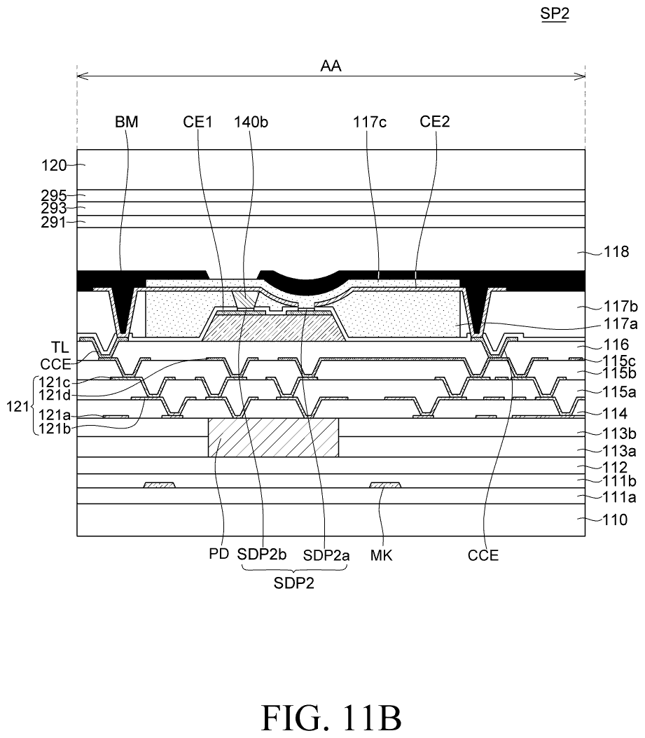

FIG. 10 is a plan view of a display apparatus according to an exemplary embodiment of the present disclosure. FIG. 10 is a cross-sectional view of the same area as in FIG. 8. FIGS. 11A and 11B are cross-sectional views of a display apparatus according to an exemplary embodiment of the present disclosure. FIGS. 10 to 11B are views for explaining a case that at least any one micro LED (ED) is not transferred and as an example, a case that a 2-1-th micro LED 140a is not transferred to a 2-1-th sub pixel SP2a. Specifically, FIG. 11A is a cross-sectional view of an active area AA of a 1-1-th sub pixel SP1a, a 2-1-th sub pixel SP2a, and a 3-1-th sub pixel SP3a. FIG. 11B is an enlarged cross-sectional view of a second sub pixel SP2.

Referring to FIGS. 10 to 11B, the first solder pattern SDP1 includes a 1-1-th solder pattern SDP1a disposed in a 1-1-th sub pixel SP1a and a 1-2-th solder pattern disposed in a 1-2-th sub pixel SP2a. The second solder pattern SDP2 includes a 2-1-th solder pattern SDP2a disposed in a 2-1-th sub pixel SP2a and a 2-2-th solder pattern SDP2b disposed in a 2-2-th sub pixel SP2b. The third solder pattern SDP3 includes a 3-1-th solder pattern SDP3a disposed in a 3-1-th sub pixel SP3a and a 3-2-th solder pattern SDP3b disposed in a 3-2-th sub pixel SP3b, but it is not limited thereto.

In any one of the plurality of sub pixels, a micro LED (ED) may not be transferred due to a process error. For example, as illustrated in FIGS. 10 to 11B, a micro LED (ED) is not transferred to the 2-1-th sub pixel SP2a. In the second sub pixel SP2, the micro LED (ED) is disposed on only the 2-2-th solder pattern SDP2b between the 2-1-th solder pattern SDP2a and the 2-2-th solder pattern SDP2b disposed on the bank BNK of the second sub pixel SP2. That is, the 2-2-th micro LED 140b is normally transferred in the 2-2-th sub pixel SP2b, but the 2-1-th micro LED 140a may not be transferred to the 2-1-th sub pixel SP2a due to the loss of the 2-1-th micro LED. Therefore, the 2-1-th sub pixel SP2a does not emit light so that the 2-2-th sub pixel SP2b of the second sub pixel SP2 is used, instead of the 2-1-th sub pixel SP2a.

The first optical layer 117a may be disposed so as to cover the plurality of micro LEDs (ED) and the bank BNK in the plurality of sub pixels. At this time, the first optical layer 117a may be partially removed from a sub pixel in which the micro LED (ED) is not transferred, for example, the 2-1-th sub pixel SP2a.

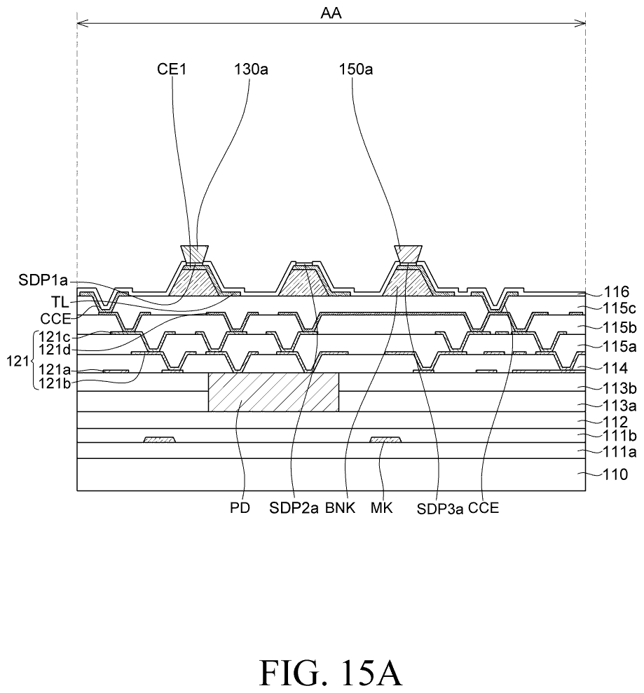

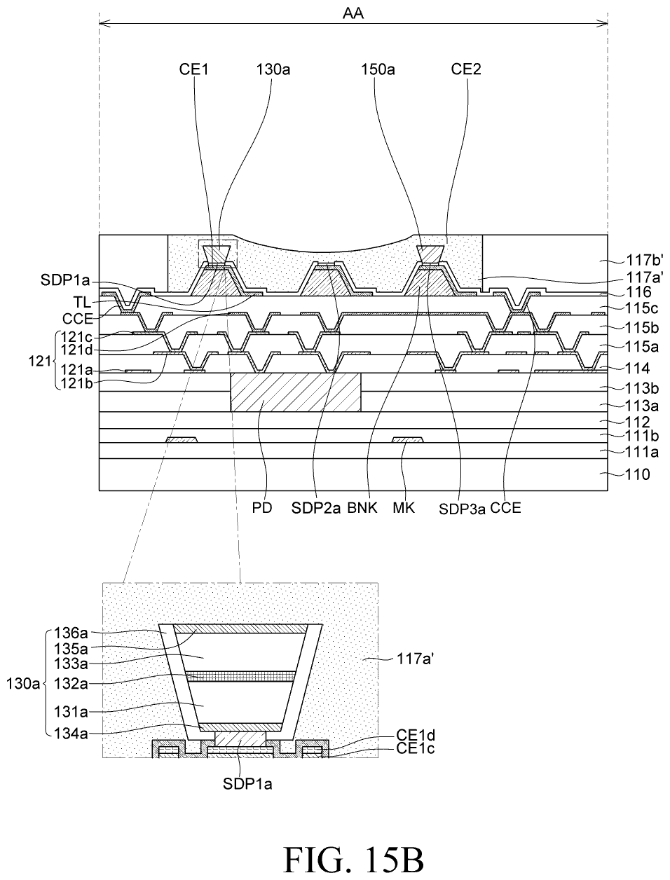

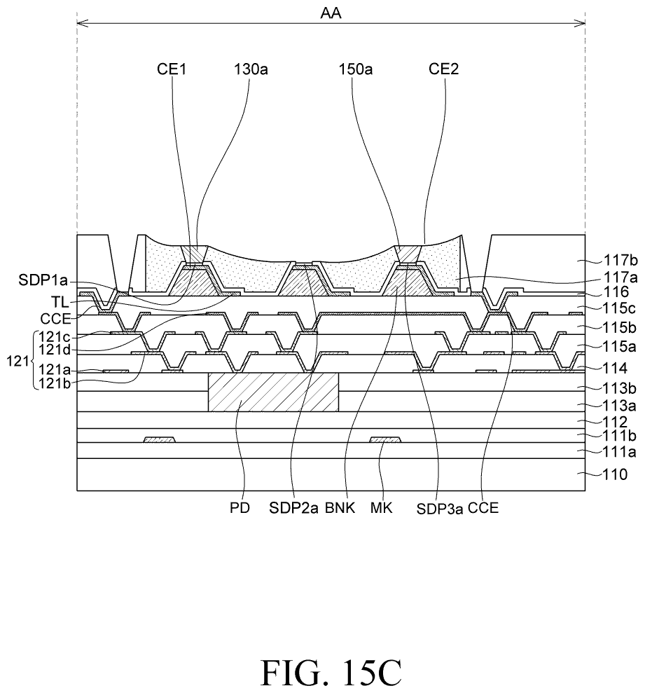

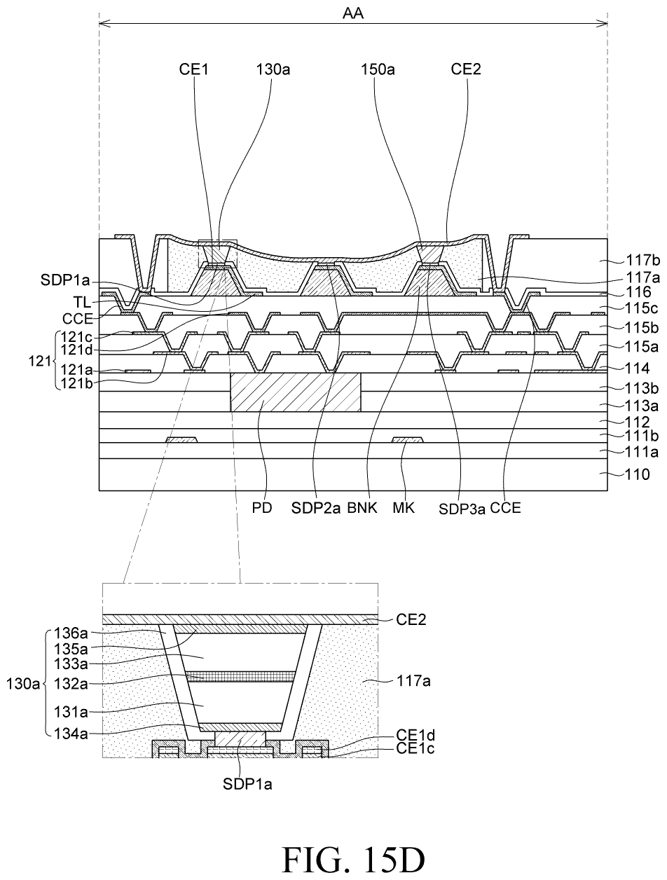

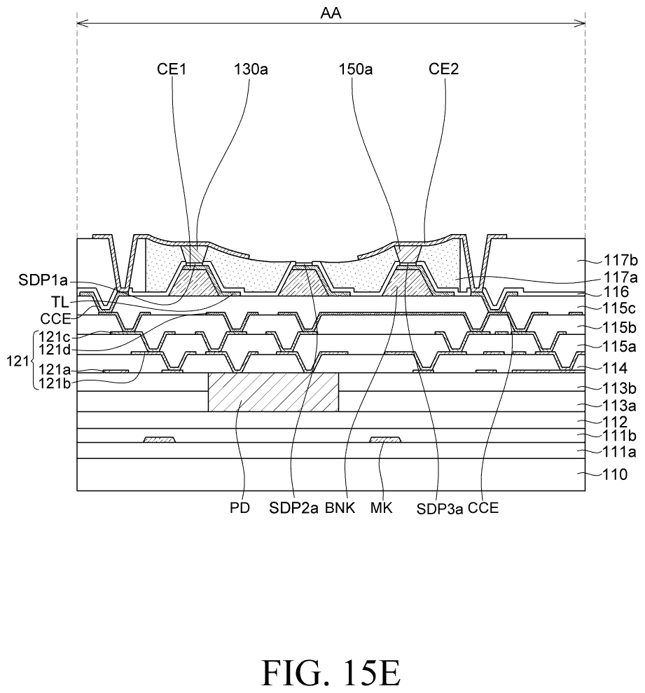

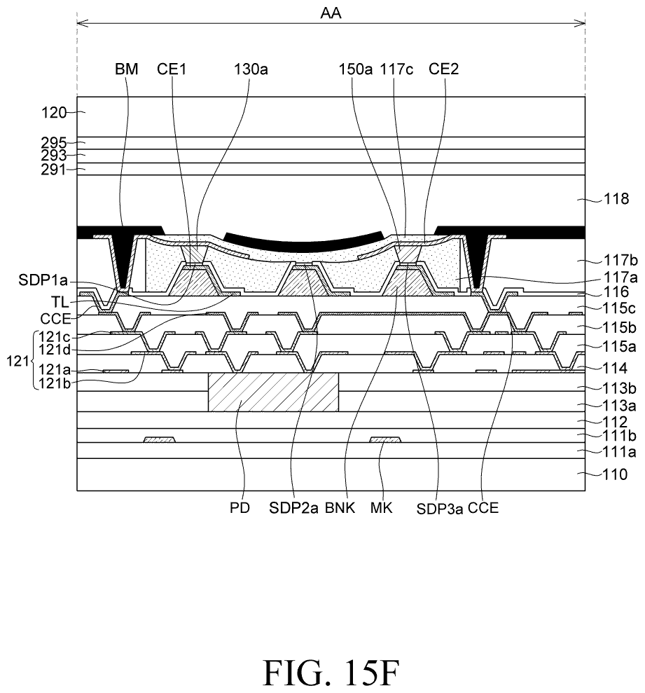

For example, the first optical layer 117a which is disposed on the upper surface of the micro LED (ED) to connect the cathode electrode 135 of the micro LED (ED) and the second electrode CE2 is removed. That is, the first optical layer 117a may be partially removed by the opening process of the cathode electrode 135. At this time, the micro LED (ED) was not transferred to the 2-1-th sub pixel SP2a so that the first optical layer 117a is disposed on the 2-1-th solder pattern SDP2a and the first optical layer 117a disposed on the 2-1-th solder pattern SDP2a is removed during the manufacturing process. At this time, the first optical layer 117a disposed on the 2-1-th solder pattern SDP2a is entirely removed according to an exposure amount to expose the 2-1-th solder pattern SDP2a, which will be described in more detail with reference to FIGS. 15A to 15D.

In the meantime, the first optical layer 117a disposed on the second sub pixel SP2 may include an inclined portion. For example, the first optical layer 117a may be inclined in the 2-1-th sub pixel SP2a. For example, the more adjacent to the 2-1-th solder pattern SDP2a of the 2-1-th sub pixel SP2a, the more the exposure amount so that a thickness at which the first optical layer 117a is removed is increased. Therefore, the more adjacent to the 2-1-th solder pattern SDP2a, the smaller the height of the first optical layer 117a, but it is not limited thereto.

Further, the first optical layer 117a includes an inclined portion between the 2-1-th sub pixel SP2a and an adjacent sub pixel.

For example, in the 2-2-th sub pixel SP2b, the 1-1-th sub pixel SP1a, and the 3-1-th sub pixel SP3a which are adjacent sub pixels to which the micro LED (ED) is normally transferred, a height of the first optical layer 117a is similar to a height of the micro LED (ED). In contrast, in the 2-1-th sub pixel SP2a, the height of the first optical layer 117a is lower than that of the adjacent micro LED (ED).

Therefore, the first optical layer 117a disposed in the adjacent sub pixel may flow to the 2-1-th sub pixel SP2a due to the height difference. Accordingly, as the first optical layer 117a is adjacent to the 2-1-th sub pixel SP2a, the height is gradually decreased, but it is not limited thereto.

That is, the upper surface of the first optical layer 117a disposed in the second sub pixel SP2 may be inclined between the 2-1-th solder pattern SDP2a and the light emitting diode ED of the adjacent sub pixel, but is not limited thereto.

The second electrode CE2 is disposed on the first optical layer 117a. The second electrode CE2 is partially removed from the sub pixel in which the micro LED (ED) is not transferred. For example, the lighting test of the micro LED (ED) is performed to detect a sub pixel in which the micro LED (ED) is not transferred and remove a part of the second electrode CE2 disposed in the corresponding sub pixel. For example, when the micro LED (ED) is not transferred onto the solder pattern SDP, a second electrode CE2 to be disposed on the micro LED (ED) is disposed on the solder pattern SDP. Therefore, the short-circuit defect between the solder pattern SDP and the second electrode CE2 may occur. Accordingly, a sub pixel in which the micro LED (ED) is not transferred is detected by the lighting test and the second electrode CE2 of the corresponding sub pixel is removed to suppress the short-circuit defect between the solder pattern SDP and the second electrode CE2. For example, the second electrode CE2 is removed by a digital lithography (DLT) technique, but is not limited thereto.

For example, in the display apparatus 1000 according to the exemplary embodiment of the present disclosure, the micro LED (ED) is not transferred to the 2-1-th sub pixel SP2a so that it is detected that the 2-1-th sub pixel SP2a is not lit during the lighting test. Next, the 2-1-th sub pixel is detected as a defect pixel which is not lit so that the second electrode CE2 disposed in the 2-1-th sub pixel SP2a is partially removed. For example, the second electrode CE2 is removed from only an area which overlaps the 2-1-th solder pattern SDP2a to expose the 2-1-th solder pattern SDP2a. That is, the second electrode CE2 is disposed in an area excluding an area overlapping the 2-1-th solder pattern SDP2a from the 2-1-th sub pixel SP2a. Therefore, the end of the second electrode CE2 is disposed on the passivation layer 116 which is disposed so as to enclose the 2-1-th solder pattern SDP2a, but is not limited thereto.

In the meantime, the second electrode CE2 is disposed on the first optical layer 117a, along an inclination of the first optical layer 117a. That is, the first optical layer 117a has an inclined portion in the 2-1-th sub pixel SP2a so that the second electrode CE2 also includes the inclined portion in the 2-1-th sub pixel SP2a.

Accordingly, the more adjacent to the 2-1-th solder pattern SDP2a, the smaller the height of the second electrode CE2. Accordingly, a part of the second electrode CE2 disposed in the second sub pixel SP2, for example, at least a part disposed in the 2-1-th sub pixel SP2a may have a height lower than that of a part disposed in the remaining sub pixel. That is, the inclined portion of the second electrode CE2 has a height lower than that of the micro LED (ED) disposed in each sub pixel, but is not limited thereto.

The third optical layer 117c is disposed on the second electrode CE2. The second electrode CE2 exposes the 2-1-th solder pattern SDP2a so that the third optical layer 117c disposed on the second electrode CE2 is in contact with the 2-1-th solder pattern SDP2a in the 2-1-th sub pixel SP2a, but is not limited thereto.

Further, the third optical layer 117c includes an inclined portion, similar to the first optical layer 117a and the second electrode CE2. That is, the first optical layer 117a and the second electrode CE2 have an inclined portion in the 2-1-th sub pixel SP2a so that the third optical layer 117c also includes an inclined portion in the 2-1-th sub pixel SP2a. For example, the third optical layer 117c has a concave portion with the 2-1-th solder pattern SDP2a at the center, similar to the first optical layer 117a.

That is, the more adjacent to the 2-1-th solder pattern SDP2a, the smaller the height of the third optical layer 117c. Accordingly, a part of the third optical layer 117c disposed in the second sub pixel SP2, for example, at least a part disposed in the 2-1-th sub pixel SP2a may have a height lower than that of a part disposed in the remaining sub pixel, but is not limited thereto.

A black matrix BM is disposed on the second electrode CE2, the first optical layer 117a, the second optical layer 117b, and the third optical layer 117c. The black matrix BM includes an inclined portion, similar to the second electrode CE2, the first optical layer 117a, and the third optical layer 117c. That is, the second electrode CE2, the first optical layer 117a, and the third optical layer 117c have an inclined portion in the 2-1-th sub pixel SP2a so that the black matrix BM also includes an inclined portion in the 2-1-th sub pixel SP2a. For example, the black matrix BM has a concave portion with the 2-1-th solder pattern SDP2a at the center.

That is, the more adjacent to the 2-1-th solder pattern SDP2a, the smaller the height of the black matrix BM. Therefore, at least a part of the black matrix BM which is disposed in the 2-1-th sub pixel SP2a may have a height lower than that of a part disposed in the remaining pixel, but is not limited thereto.

In the meantime, the black matrix BM may be disposed so as to cover a part of the inclination of the upper surface of the third optical layer 117c. Accordingly, the inclination of the upper surface of the black matrix BM may be gentler than the inclination of the third optical layer 117c, but is not limited thereto.

The display apparatus is manufactured by forming a plurality of micro LEDs on a wafer and transferring a plurality of micro LEDs to a substrate of the display panel. However, during the process of transferring the plurality of micro LEDs having a micro size from the wafer to the substrate, various defects may be caused. For example, in some sub pixels, a non-transferring defect that the micro LED is not transferred to the substrate of the panel due to the loss of the micro LED may occur.

As described above, when a subsequent process is performed in a state in which the transferring defect occurs, a short-circuit defect between electrodes may occur. For example, connection electrodes which need to be individually connected to the n-type electrode and the p-type electrode of the micro LED are not separately disposed, but are in contact with each other to cause a short-circuit defect.

For example, if the micro LED has a vertical structure, processes of transferring the micro LED onto the solder pattern of the display panel, placing an optical layer which encloses the micro LED to fix the micro LED, and then placing and connecting a second connection electrode on the cathode electrode of the micro LED are sequentially performed. At this time, in order to connect the cathode electrode of the micro LED and the second connection electrode, a process of opening the cathode electrode of the micro LED is performed after transferring the micro LED. For example, the optical layer which encloses the micro LED may be disposed to cover to the upper portion of the micro LED, that is, the cathode electrode of the micro LED. Therefore, a process of removing the optical layer disposed above the micro LED to expose the cathode electrode of the micro LED is performed. For example, the optical layer disposed above the micro LED is exposed and developed to be removed.

At this time, in the sub pixel in which a non-transferring defect occurs, the optical layer is directly disposed on the solder pattern, rather than the micro LED. Accordingly, all the optical layers disposed on the solder pattern are removed according to an exposure amount of the optical layer to expose a solder pattern disposed below the optical layer.

As described above, in the state in which the solder pattern is exposed, when a process of placing the second connection electrode on the micro LED is performed, in the sub pixel in which the non-transferring defect occurs, the second connection electrode is directly disposed on the solder pattern to be in contact with each other. Accordingly, the short-circuit defect between the solder pattern and the second connection electrode may occur.

In the display apparatus 1000 according to the exemplary embodiment of the present disclosure, after the transferring process of the micro LED (ED), a sub pixel in which the micro LED (ED) is not transferred is detected by the lighting test to partially remove the second electrode CE2 from the corresponding sub pixel. For example, the lighting test is performed after transferring the micro LED (ED) onto the solder pattern SDP disposed in each sub pixel and connecting the micro LED with the second electrode. At this time, a defect sub pixel in which the micro LED (ED) is not transferred so that the light is not emitted is detected by the lighting test. Next, the second electrode CE2 in an area of the sub pixel which overlaps the solder pattern SDP may be removed. Therefore, the short-circuit detect that the micro LED (ED) is not transferred onto the solder pattern SDP so that the second electrode CE is disposed on the solder pattern SDP to be in contact with the solder pattern SDP may be suppressed. Accordingly, in the display apparatus 1000 according to the exemplary embodiment of the present disclosure, even though the non-transferring defect of the micro LED (ED) occurs, the short-circuit defect due to the overlapping of the solder pattern SDP and the second electrode CE2 may be suppressed.

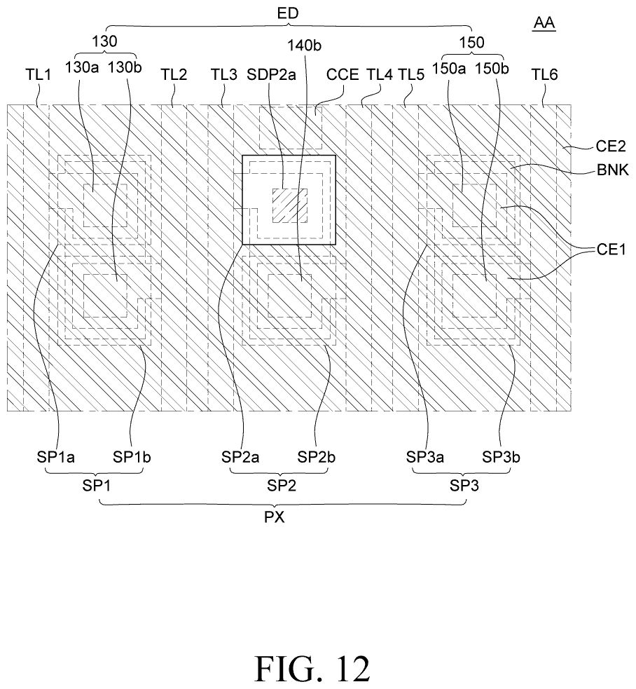

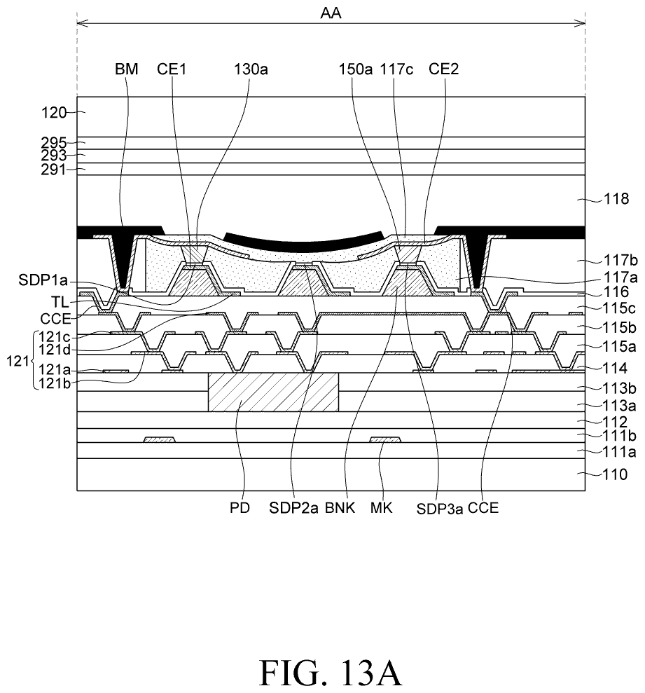

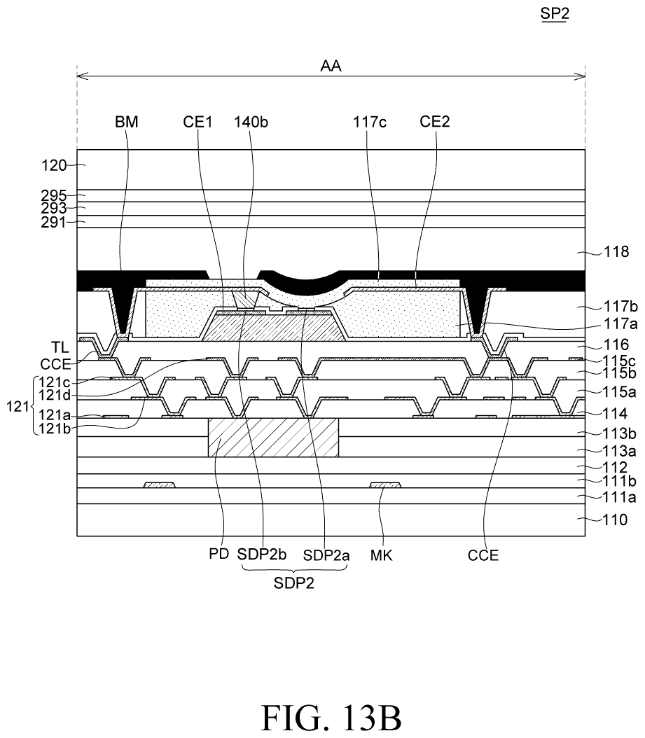

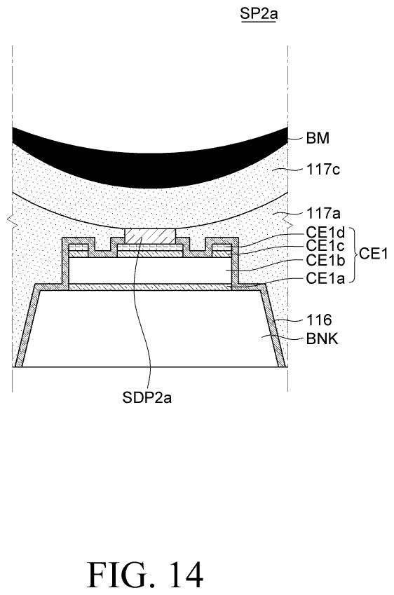

FIG. 12 is a plan view of a display apparatus according to another exemplary embodiment of the present disclosure. FIGS. 13A and 13B are plan views of a display apparatus according to another exemplary embodiment of the present disclosure. FIG. 14 is a cross-sectional view of a display apparatus according to another exemplary embodiment of the present disclosure. FIGS. 15A to 15F are process diagrams of a manufacturing method of a display apparatus according to another exemplary embodiment of the present disclosure. The only difference between a display apparatus of FIGS. 12 to 15F and the display apparatus of FIGS. 10 to 11B is a second electrode CE2, but the other component is substantially the same, so that a redundant description will be omitted.

Referring to FIGS. 12 to 14, for example, the micro LED (ED) is not transferred to any one of the second sub pixels SP2 due to the process error. For example, the micro LED (ED) is disposed on only the 2-2-th solder pattern SDP2b between the 2-1-th solder pattern SDP2a and the 2-2-th solder pattern SDP2b disposed on the bank BNK of the second sub pixel SP2. That is, the 2-2-th micro LED 140b is disposed in the 2-2-th sub pixel SP2b, but the 2-1-th micro LED 140a is not disposed in the 2-1-th sub pixel SP2a. Therefore, the 2-1-th sub pixel SP2a does not emit light so that the 2-2-th sub pixel SP2b of the second sub pixel SP2 is used, instead of the 2-1-th sub pixel SP2a.

At this time, the second electrode CE2 is disposed in an area excluding the 2-1-th sub pixel SP2a. That is, the second electrode CE2 is removed from the 2-1-th sub pixel SP2a itself. Therefore, the second electrode CE2 may expose not only the 2-1-th solder pattern SDP2a, but also the first optical layer 117a adjacent to the 2-1-th solder pattern SDP2a. For example, the second electrode CE2 may expose at least a part of the upper surface of the first optical layer 117a adjacent to the 2-1-th solder pattern SDP2a, but is not limited thereto.

Accordingly, the third optical layer 117c disposed on the second electrode CE2 may be in contact with not only the 2-1-th solder pattern SDP2a exposed by the second electrode CE2, but also at least a part of the upper surface of the first optical layer 117a, but is not limited thereto.

Hereinafter, a manufacturing method of a display apparatus according to another exemplary embodiment of the present disclosure will be described in detail with reference to FIGS. 15A to 15D. FIGS. 15A to 15D are process diagrams of a manufacturing method of a display apparatus according to another exemplary embodiment of the present disclosure.

First, referring to FIG. 15A, a transferring process of the micro LED (ED) is performed. The micro LED (ED) is disposed on the bank BNK disposed in each sub pixel and for example, disposed on the solder pattern SDP disposed on the bank BNK.

For example, the 1-1-th micro LED 130a is disposed on the 1-1-th solder pattern SDP1a in the 1-1-th sub pixel SP1a. The 3-1-th micro LED 150a is disposed on the 3-1-th solder pattern SDP3a in the 3-1-th sub pixel SP3a. In contrast, in the 2-1-th sub pixel SP2a, the 2-1-th micro LED 140a may not be transferred due to the loss of the 2-1-th micro LED 140a.

Referring to FIG. 15B, a process of placing an initial first optical layer 117a′ so as to enclose the micro LED (ED) is performed. For example, in a sub pixel in which the micro LED (ED) is normally transferred, the initial first optical layer 117a′ is disposed so as to cover an upper portion of the micro LED (ED). Therefore, the initial first optical layer 117a′ is disposed so as to cover the cathode electrode 135 of the micro LED (ED).

In the meantime, in the 2-1-th sub pixel SP2a in which a non-transferring defect of the micro LED (ED) occurs, the initial first optical layer 117a′ is disposed on the 2-1-th solder pattern SDP2a.

Next, a process of placing an initial first optical layer 117a′ so as to enclose the initial first optical layer 117a′ is performed. However, the process of placing the initial second optical layer 117b may be performed after the process of forming the first optical layer 117 to be described below without being limited thereto.

Next, referring to FIG. 15C, a process of forming the first optical layer 117a by removing a part of the initial first optical layer 117a′ is performed to expose the cathode electrode 135 of the micro LED (ED). For example, in the subsequent process, the cathode electrode 135 of the micro LED (ED) needs to be connected to the second electrode CE2 disposed above the micro LED (ED). Therefore, the initial first optical layer 117a′ which covers the cathode electrode 135 of the micro LED (ED) is removed to expose the cathode electrode 135 of the micro LED (ED).

For example, a mask is open only in an area corresponding to the solder pattern SDP in which the micro LED (ED) will be disposed to expose and develop the initial first optical layer 117a disposed above the micro LED (ED) to be removed, but is not limited thereto.

Therefore, an upper portion of the 1-1-th micro LED 130a, an upper portion of the 3-1-th micro LED 150a, and an upper portion of the 2-1-th solder pattern SDP2a are open to expose and develop the initial first optical layer 117a′ disposed above the 1-1-th micro LED 130a, the 3-1-th micro LED 150a, and the 2-1-th solder pattern SDP2a.

At this time, in the 2-1-th sub pixel SP2a, the entire initial first optical layer 117a′ disposed on the 2-1-th solder pattern SDP2a is removed according to the exposure amount of the initial first optical layer 117a′ to expose the 2-1-th solder pattern SDP2a.

In the meantime, the first optical layer 117a may have an inclination in an area overlapping the 2-1-th solder pattern SDP2a. For example, the first optical layer 117a disposed in the 2-1-th sub pixel SP2a may have a height lower than that of the first optical layer 117a disposed in the adjacent sub pixel. For example, in a sub pixel in which the micro LED (ED) is normally transferred, the height of the first optical layer 117a is equal to the height of the micro LED (ED). In contrast, in the 2-1-th sub pixel SP2a, the height of the first optical layer 117a is lower than that of the micro LED (ED) disposed in the adjacent sub pixel.

Therefore, the first optical layer 117a disposed in the adjacent sub pixel may flow to the 2-1-th sub pixel SP2a due to the height difference. As the first optical layer 117a is adjacent to the 2-1-th sub pixel SP2a, the height may be gradually decreased, but is not limited thereto.

Further, a process of forming a second optical layer 117b including a contact hole by partially removing the initial second optical layer 117b′ is performed. The contact hole of the second optical layer 117b may be a contact hole for connecting the second electrode CE2 and a signal line TL, but is not limited thereto.

Next, referring to FIG. 15D, a process of placing the initial second electrode CE2′ on the micro LED (ED) to connect the initial second electrode to the cathode electrode 135 of the micro LED (ED) may be performed. At this time, in the 2-1-th sub pixel SP2a, the 2-1-th solder pattern SDP2a is exposed by the process of opening the cathode electrode 135 so that the initial second electrode CE2′ is disposed on the 2-1-th solder pattern SDP2a to be in contact with the 2-1-th solder pattern SDP2a.

In the meantime, the initial second electrode CE2′ is disposed along the inclination of the first optical layer 117a. Accordingly, the upper surface of the initial second electrode CE2′ may have a concave shape in the 2-1-th sub pixel SP2a, but is not limited thereto.

Next, referring to FIG. 15E, processes of detecting a defective sub pixel by the lighting test and forming a second electrode CE2 by removing the initial second electrode CE2′ of the corresponding sub pixel are sequentially performed.

For example, a defect of the 2-1-th sub pixel SP2a is detected by the lighting test. Therefore, the second electrode CE2 is formed by removing a part of the initial second electrode CE2′ which is disposed in the 2-1-th sub pixel SP2a. For example, the initial second electrode CE2′ is removed by a digital lithography (DLT) technique, but is not limited thereto.

That is, the second electrode CE2 which is formed by removing a part of the initial second electrode CE2′ is disposed in only an area excluding the 2-1-th sub pixel SP2a. Accordingly, the second electrode CE2 is disposed to be spaced apart from the 2-1-th solder pattern SDP2a to suppress the short-circuit defect between the 2-1-th solder pattern SDP2a and the second electrode CE2.

Finally, referring to FIG. 15F, various configurations including a third optical layer 117c and a black matrix BM are sequentially disposed on the first optical layer 117a and the second electrode CE2 to finish the manufacturing process of the display apparatus.

The third optical layer 117c and the black matrix BM are disposed along the inclination of the first optical layer and the second electrode CE2 in the 2-1-th sub pixel. Therefore, top surfaces of the third optical layer 117c and the black matrix BM may have a concave shape. In the meantime, the black matrix BM is disposed so as to cover a part of an inclination of the upper surface of the third optical layer 117c so that the inclination of the upper surface of the black matrix BM may be gentler than the inclination of the third optical layer 117c, but is not limited thereto.

In the display apparatus according to another exemplary embodiment of the present disclosure, after the transferring process of the micro LED (ED), a sub pixel in which the micro LED (ED) is not transferred is detected by the lighting test to partially remove the second electrode CE2 from the corresponding sub pixel. For example, the lighting test is performed after transferring the micro LED (ED) onto the solder pattern SDP disposed in each sub pixel and connecting the micro LED with the second electrode. At this time, a defect sub pixel in which the micro LED (ED) is not transferred so that the light is not emitted is detected by the lighting test. Next, the second electrode CE2 is removed from the corresponding sub pixel. That is, the second electrode CE2 is disposed in only a sub pixel excluding the sub pixel in which the micro LED (ED) is not transferred. Therefore, the short-circuit detect that the micro LED (ED) is not transferred onto the solder pattern SDP so that the second electrode CE is disposed on the solder pattern SDP to be in contact with the solder pattern SDP may be more effectively suppressed. Accordingly, in the display apparatus according to another exemplary embodiment of the present disclosure, even though the non-transferring defect of the micro LED (ED) occurs, the short-circuit defect due to the overlapping of the solder pattern SDP and the second electrode CE2 may be suppressed.

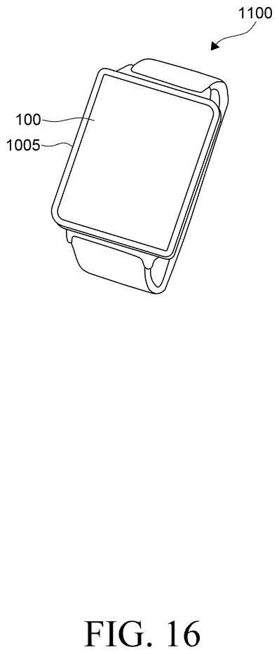

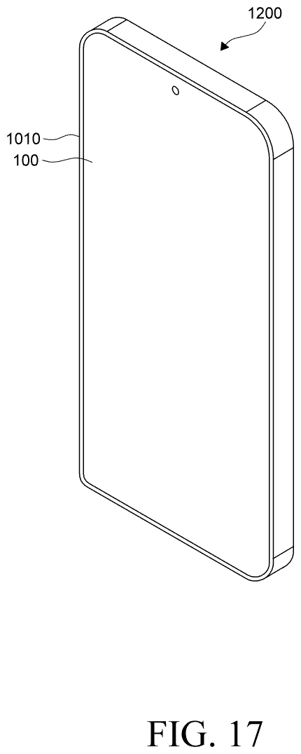

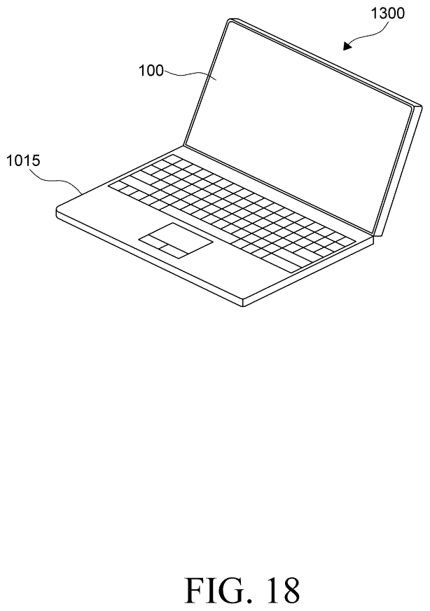

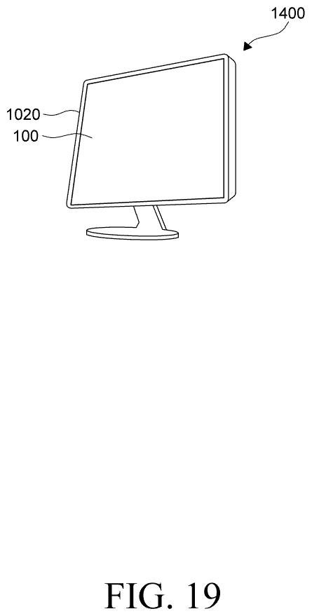

FIGS. 16 to 19 are views illustrating devices to which a display apparatus according to exemplary embodiments of the present disclosure is applied.

Referring to FIGS. 16 to 19, the display apparatus 1000 according to the exemplary embodiments of the present disclosure may be included in various apparatuses or electronic apparatuses. For example, referring to FIGS. 16 to 19, various electronic apparatuses may include a wearable device 1100, a mobile device 1200, a laptop 1300, and a monitor, or TV 1400, but the exemplary embodiments of the present disclosure are not limited thereto.

Each of the wearable device 1100, the mobile device 1200, the laptop 1300, and the monitor or the TV 1400 may include case parts 1005, 1010, 1015, and 1020 and the display panel 100, 200, 300 and the display apparatus 1000 according to the exemplary embodiments of the present disclosure described in FIGS. 1 to 15.

For example, the display apparatus according to an exemplary embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.

The exemplary embodiments of the present disclosure can also be described as follows:

According to an aspect of the present disclosure, there is provided a display apparatus. The display apparatus includes a substrate, a pixel driving circuit disposed on the substrate, a bank disposed on the pixel driving circuit, a first electrode which is disposed on the bank and is connected to the pixel driving circuit, a plurality of solder patterns disposed on the first electrode, a micro LED disposed on one solder pattern, among the plurality of solder patterns, a first optical layer which is disposed so as to enclose the micro LED and exposes another solder pattern, among the plurality of solder patterns and a second electrode which is disposed on the micro LED and the first optical layer and exposes the another solder pattern.

An upper surface of the first optical layer may have an inclination between the another solder pattern and the micro LED.

The second electrode may include an inclined portion in an area adjacent to the another solder pattern.

A height of the inclined portion of the second electrode may be lower than a height of the micro LED.

The display apparatus may further include a second optical layer which is disposed on the second electrode and is formed of an organic material in which micro particles are dispersed. The second optical layer may be in contact with the another solder pattern.

The second electrode may expose a part of an upper surface of the first optical layer adjacent to the another solder pattern and the second optical layer may be in contact with the part of the upper surface of the first optical layer adjacent to the another solder pattern.

The display apparatus may further include a black matrix disposed on the second electrode and the second optical layer. Top surfaces of the first optical layer and the black matrix have a concave shape in an area overlapping the another solder pattern and an inclination of the upper surface of the black matrix may be gentler than an inclination of the upper surface of the first optical layer.

The display apparatus may further include a passivation layer which is disposed so as to enclose the bank and the solder pattern. An end of the second electrode may be disposed on the passivation layer.

The micro LED may include an anode electrode, a first semiconductor layer disposed on the anode electrode, an active layer disposed on the first semiconductor layer, a second semiconductor layer disposed on the active layer and a cathode electrode disposed on the second semiconductor layer.

The first electrode may be disposed below the micro LED to electrically connect the pixel driving circuit and the anode electrode of the micro LED, the plurality of solder patterns may be disposed between the first electrode and the anode electrode, and the first electrode and the anode electrodes may be electrically connected by eutectic bonding using the plurality of solder patterns.

According to another aspect of the present disclosure, there is provided a display apparatus. The display apparatus includes a substrate including a plurality of sub pixels including a first sub pixel, a second sub pixel, and a third sub pixel, a plurality of pixel driving circuits disposed on the substrate, a plurality of banks which is disposed in each of the plurality of sub pixels and is disposed on the plurality of pixel driving circuits, a plurality of first electrodes which is disposed on the plurality of banks and is connected to the plurality of pixel driving circuits, a plurality of solder patterns which is disposed on the plurality of first electrodes in each of the plurality of sub pixels and includes a first solder pattern and a second solder pattern, a plurality of micro LEDs including one pair of first micro LEDs which are disposed on the first solder pattern and the second solder pattern, respectively, in the first sub pixel, and emit the same color light, one second micro LED which is disposed on the second solder pattern in the second sub pixel and one pair of third micro LEDs which are disposed on the first solder pattern and the second solder pattern, respectively, in the third sub pixel, and emit the same color light and a plurality of second electrodes which is disposed on the plurality of micro LEDs and exposes the second solder pattern of the second sub pixel.

The first sub pixel may include a 1-1-th sub pixel and a 1-2-th sub pixel, the second sub pixel may include a 2-1-th sub pixel and a 2-2-th sub pixel, and the third sub pixel may include a 3-1-th sub pixel and a 3-2-th sub pixel. The first solder pattern may include a 1-1-th solder pattern disposed in the 1-1-th sub pixel and a 1-2-th solder pattern disposed in the 1-2-th sub pixel. The second solder pattern may include a 2-1-th solder pattern disposed in the 2-1-th sub pixel and a 2-2-th solder pattern disposed in the 2-2-th sub pixel. The third solder pattern may include a 3-1-th solder pattern disposed in the 3-1-th sub pixel and a 3-2-th solder pattern disposed in the 3-2-th sub pixel.

One second micro LED may be disposed on the 2-2-th solder pattern in the 2-2-th sub pixel and the plurality of second electrodes may expose the 2-1-th solder pattern of the 2-1-th sub pixel.

The plurality of second electrodes may be disposed in an area excluding the 2-1-th sub pixel.

The plurality of second electrodes may be disposed in only an area excluding an area overlapping the 2-1-th solder pattern in the 2-1-th sub pixel.

The display apparatus may further include an optical layer disposed so as to enclose the plurality of micro LEDs. A height of at least a part of the optical layer disposed in the 2-1-th sub pixel may be lower than a height of the part disposed in the 2-2-th sub pixel, the first sub pixel, and the third sub pixel.

The display apparatus may further include an optical layer disposed on the plurality of second electrodes. A height of at least a part of the optical layer disposed in the 2-1-th sub pixel may be lower than a height of the part disposed in the 2-2-th sub pixel, the first sub pixel, and the third sub pixel.

The display apparatus may further include a black matrix disposed on the second electrode and the optical layer. A height of at least a part of the black matrix disposed in the 2-1-th sub pixel may be lower than a height of the part disposed in the 2-2-th sub pixel, the second sub pixel, and the third sub pixel.

The plurality of micro LEDs may include an anode electrode, a first semiconductor layer disposed on the anode electrode, an active layer disposed on the first semiconductor layer, a second semiconductor layer disposed on the active layer, and a cathode electrode disposed on the second semiconductor layer and have a vertical type structure.

The plurality of solder patterns may be disposed between the plurality of first electrodes and the anode electrode, and the anode electrode may be bonded to the plurality of first electrodes by eutectic bonding using the plurality of solder patterns.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate;
a pixel driving circuit disposed on the substrate;
a bank disposed on the pixel driving circuit;
a first electrode disposed on the bank, the first electrode connected to the pixel driving circuit;
a plurality of solder patterns disposed on the first electrode;
a micro Light-Emitting Diode (LED) disposed on one solder pattern, among the plurality of solder patterns;
a first optical layer enclosing the micro LED and exposing another solder pattern, among the plurality of solder patterns; and
a second electrode disposed on the micro LED and the first optical layer, the second electrode exposing the another solder pattern.

2. The display apparatus according to claim 1, wherein an upper surface of the first optical layer has an inclination between the another solder pattern and the micro LED.

3. The display apparatus according to claim 1, wherein the second electrode includes an inclined portion in an area adjacent to the another solder pattern.

4. The display apparatus according to claim 3, wherein a height of the inclined portion of the second electrode is lower than a height of the micro LED.

5. The display apparatus according to claim 1, further comprising:
a second optical layer which is disposed on the second electrode and is formed of an organic material in which micro particles are dispersed,
wherein the second optical layer is in contact with the another solder pattern.

6. The display apparatus according to claim 5, wherein the second electrode exposes a part of an upper surface of the first optical layer adjacent to the another solder pattern and the second optical layer is in contact with the part of the upper surface of the first optical layer adjacent to the another solder pattern.

7. The display apparatus according to claim 5, further comprising:
a black matrix disposed on the second electrode and the second optical layer,
wherein an upper surface of the first optical layer and an upper surface of the black matrix have a concave shape in an area overlapping the another solder pattern and an inclination of the upper surface of the black matrix is gentler than an inclination of the upper surface of the first optical layer.

8. The display apparatus according to claim 1, further comprising:
a passivation layer which is disposed so as to enclose the bank and the solder pattern,
wherein an end of the second electrode is disposed on the passivation layer.

9. The display apparatus according to claim 1, wherein the micro LED includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

10. The display apparatus according to claim 9, wherein the first electrode is disposed below the micro LED to electrically connect the pixel driving circuit and the anode electrode of the micro LED, the plurality of solder patterns is disposed between the first electrode and the anode electrode, and the first electrode and the anode electrodes are electrically connected by eutectic bonding using the plurality of solder patterns.

11. A display apparatus comprising:
a substrate including a plurality of sub pixels including a first sub pixel, a second sub pixel, and a third sub pixel;
a plurality of pixel driving circuits disposed on the substrate;
a plurality of banks which are disposed in the plurality of sub pixels respectively and disposed on the plurality of pixel driving circuits respectively;
a plurality of first electrodes disposed on the plurality of banks respectively, the plurality of first electrodes connected to the plurality of pixel driving circuits respectively;
a plurality of solder patterns disposed on the plurality of first electrodes in the plurality of sub pixels respectively, each of the plurality of solder patterns including a first sub solder pattern and a second sub solder pattern;
a plurality of micro Light-Emitting Diodes (LEDs) including:
one pair of first micro LEDs which are disposed on the first sub solder pattern and the second sub solder pattern, respectively, in the first sub pixel, and emit the same color light;
one second micro LED which is disposed on the second sub solder pattern in the second sub pixel; and
one pair of third micro LEDs which are disposed on the first sub solder pattern and the second sub solder pattern, respectively, in the third sub pixel, and emit the same color light; and
a plurality of second electrodes which are disposed on the plurality of micro LEDs respectively and expose the second sub solder pattern of the second sub pixel.

12. The display apparatus according to claim 11, wherein the first sub pixel includes a 1-1-th sub pixel and a 1-2-th sub pixel, the second sub pixel includes a 2-1-th sub pixel and a 2-2-th sub pixel, and the third sub pixel includes a 3-1-th sub pixel and a 3-2-th sub pixel,
a first solder pattern includes a 1-1-th solder pattern disposed in the 1-1-th sub pixel and a 1-2-th solder pattern disposed in the 1-2-th sub pixel,
a second solder pattern includes a 2-1-th solder pattern disposed in the 2-1-th sub pixel and a 2-2-th solder pattern disposed in the 2-2-th sub pixel, and
a third solder pattern includes a 3-1-th solder pattern disposed in the 3-1-th sub pixel and a 3-2-th solder pattern disposed in the 3-2-th sub pixel.

13. The display apparatus according to claim 12, wherein the one second micro LED is disposed on the 2-2-th solder pattern in the 2-2-th sub pixel and the plurality of second electrodes exposes the 2-1-th solder pattern of the 2-1-th sub pixel.

14. The display apparatus according to claim 13, wherein the plurality of second electrodes is disposed in an area excluding the 2-1-th sub pixel.

15. The display apparatus according to claim 13, wherein the plurality of second electrodes is disposed in only an area excluding an area overlapping the 2-1-th solder pattern in the 2-1-th sub pixel.

16. The display apparatus according to claim 13, further comprising:
an optical layer enclosing the plurality of micro LEDs,
wherein a height of at least a part of the optical layer disposed in the 2-1-th sub pixel is lower than a height of a part disposed in the 2-2-th sub pixel, the first sub pixel, and the third sub pixel.

17. The display apparatus according to claim 13, further comprising:
an optical layer disposed on the plurality of second electrodes,
wherein a height of at least a part of the optical layer disposed in the 2-1-th sub pixel is lower than a height of a part disposed in the 2-2-th sub pixel, the first sub pixel, and the third sub pixel.

18. The display apparatus according to claim 17, further comprising:
a black matrix disposed on the second electrode and the optical layer,
wherein a height of at least a part of the black matrix disposed in the 2-1-th sub pixel is lower than a height of a part disposed in the 2-2-th sub pixel, the second sub pixel, and the third sub pixel.

19. The display apparatus according to claim 11, wherein the plurality of micro LEDs includes an anode electrode, a first semiconductor layer disposed on the anode electrode, an active layer disposed on the first semiconductor layer, a second semiconductor layer disposed on the active layer, and a cathode electrode disposed on the second semiconductor layer and has a vertical type structure.

20. The display apparatus according to claim 19, wherein the plurality of solder patterns is disposed between the plurality of first electrodes and the anode electrode, and the anode electrode is bonded to the plurality of first electrodes by eutectic bonding using the plurality of solder patterns.
